(19) United States
(12) Patent Application Publication
(10) Pub. No.: US 2021/0384248 A1
(43) Pub. Date: Dec. 9, 2021

(54) IMAGE SENSOR AND METHOD FOR MANUFACTURING IMAGE SENSOR

(71) Applicant: SONY SEMICONDUCTOR SOLUTIONS CORPORATION, KANAGAWA (JP)

(72) Inventor: KENJU NISHIKIDO, KANAGAWA (JP)

(21) Appl. No.: 17/284,978

(22) PCT Filed: Oct. 15, 2019
(86) PCT No.: PCT/JP2019/040414

§ 371 Date: Apr. 13, 2021

(30) Foreign Application Priority Data
Oct. 29, 2018 (JP) 2018-202985

(51) Int. Cl. H01L 27/146

(52) U.S. Cl. CPC H01L 27/14636; H01L 27/1464; H01L 27/14685; H01L 27/14623

(57) ABSTRACT

To reduce reflection of incident light at a peripheral edge portion of an image sensor and prevent deterioration of the image quality. The image sensor includes an imaging area arranged on a semiconductor substrate, a wiring area, a protective film, and a protrusion arranged at the bottom of an opening formed in the semiconductor substrate. In the imaging area, a photoelectric conversion unit formed on a semiconductor substrate and performing photoelectric conversion of incident light is arranged. The wiring area has a wiring of transmitting a signal of the photoelectric conversion unit and is arranged adjacent to the front surface of the semiconductor substrate. The protective film is arranged on the back surface that is a surface different from the front surface of the semiconductor substrate, to transmit the incident light and protect the back surface of the semiconductor. The opening is arranged in an outer peripheral area of the imaging area and opens from the protective film to any area of the semiconductor substrate and the wiring area. A protrusion is arranged at the bottom of the opening.

### TECHNICAL FIELD

The present disclosure relates to an image sensor and a method for manufacturing the image sensor. Specifically, the present disclosure relates to an image sensor having an opening formed in the vicinity of a bonding wire or in a scribe area, and a method for manufacturing the image sensor.

### BACKGROUND ART

Conventionally, an image sensor that reduces the reflection of incident light on the surface of the device has been used. This is to reduce the occurrence of flare due to reflected light and prevent deterioration of the image quality. For example, an image sensor has been proposed in which moth-eye-shaped irregularities are formed on the light-receiving surface of a semiconductor substrate constituting the image sensor to prevent reflection of incident light (see, for example, Patent Document 1). In this image sensor, the irregularities are formed in a pixel area in which a plurality of pixels including a light receiving portion having a photoelectric conversion function is arranged to prevent reflection of incident light. The irregularities can be formed by precipitating a 111 face by wet-etching a 100 face on the surface of the semiconductor substrate to form protrusions having a quadrangular pyramid shape.

### CITATION LIST

### Patent Document

Patent Document 1: Japanese Patent Application Laid-Open No. 2013-033864

### SUMMARY OF THE INVENTION

### Problems to be Solved by the Invention

In the above-mentioned conventional technique, there is a problem that the irregularities cannot be formed on a peripheral edge portion, which is an area other than the pixel area, and the reflection of incident light in the area cannot be reduced. In back-illuminated image sensors in which the back surface side of the semiconductor substrate is irradiated with incident light, a bonding wire for connecting the image sensor and an external substrate or the like is connected to a pad arranged in a deep part of the image sensor. An opening is formed in the vicinity of the pad, and the bonding wire is connected through the opening. Usually, in order to insert a test apparatus for measuring the adhesive strength of a bonding wire connected to a pad, an opening having a depth substantially equal to that of the pad is formed adjacent to the connection portion. When the incident light is reflected in the opening for testing, the reflected light is further reflected by the bonding wire and incident on the image sensor, causing flare.

Furthermore, the image sensor is manufactured by separating a plurality of image sensors formed on a semiconductor wafer into individual pieces. This separation into individual pieces can be performed by cutting the semiconductor wafer along the openings (grooves) formed at the boundaries of the plurality of image sensors. Reflection of incident light also occurs in these openings. As described above, the above-mentioned conventional technique has a problem that the reflection of the incident light at the peripheral edge portion of the image sensor cannot be prevented and the deterioration of the image quality cannot be prevented.

The present disclosure has been made in view of the above-mentioned problems, and an object of the present disclosure is to reduce reflection of incident light at the peripheral edge portion of the image sensor and prevent deterioration of the image quality.

### Solutions to Problems

The present disclosure has been made to solve the above-mentioned problems, and a first aspect thereof is an image sensor including: an imaging area in which a photoelectric conversion unit is formed on a semiconductor substrate and performs photoelectric conversion of incident light is arranged; a wiring area having a wiring of transmitting a signal of the photoelectric conversion unit and arranged adjacent to a front surface of the semiconductor substrate; a protective film that is arranged on a back surface that is a surface different from the front surface of the semiconductor substrate, and transmits the incident light and protects the back surface of the semiconductor; an opening arranged in an outer peripheral area of the imaging area and opened from the protective film to any area of the semiconductor substrate and the wiring area; and a protrusion arranged at a bottom of the opening.

Furthermore, in the first aspect, the opening may be arranged in a vicinity of a connection portion arranged in the wiring area and used for connection with outside.

Furthermore, in the first aspect, the opening may be a scribe area when an own image sensor formed on a semiconductor wafer is separated into individual pieces.

Furthermore, in the first aspect, the protrusion may include at least one of the semiconductor substrate, the wiring area, or the protective film.

Furthermore, in the first aspect, the protrusion may be formed by transferring a shape of the protective film having been patterned to one of the semiconductor substrate and the wiring area.

Furthermore, in the first aspect, the protrusion may be formed by the transfer when etching is performed using the patterned protective film as a mask.

Furthermore, in the first aspect, the protrusion may be arranged at the bottom of the opening by being formed on the back surface of the semiconductor substrate before the protective film is arranged and by opening the arranged protective film to the semiconductor substrate.

Furthermore, in the first aspect, the protrusion may be formed by etching the protective film and the semiconductor substrate by using a resist formed on the protective film as a mask.

Furthermore, in the first aspect, the protrusion may include the wiring area arranged in a recess formed on the front surface of the semiconductor substrate before the wiring area is arranged.

Furthermore, in the first aspect, the image sensor may further include: an on-chip lens that is arranged adjacent to the protective film and collects the incident light to the photoelectric conversion unit, in which the protrusion may be formed by transferring a shape of the on-chip lens to one of the semiconductor substrate and the wiring area.

Furthermore, in the first aspect, the protrusion may include the protective film arranged in a recess formed on the back surface of the semiconductor substrate before the protective film is arranged.

Furthermore, a second aspect of the present disclosure is a method for manufacturing an image sensor, the method including: an imaging area forming step of forming, on a semiconductor substrate, an imaging area in which a photoelectric conversion unit that performs photoelectric conversion of incident light is arranged; a wiring area arranging step of arranging a wiring area having a wiring of transmitting a signal of the photoelectric conversion unit, adjacent to a front surface of the semiconductor substrate; a protective film arranging step of arranging a protective film that is arranged on a back surface that is a surface different from the front surface of the semiconductor substrate, and transmits the incident light and protects the back surface of the semiconductor; an opening forming step of forming an opening arranged in an outer peripheral area of the imaging area and opened from the protective film to any area of the semiconductor substrate and the wiring area; and a protrusion arranging step of arranging a protrusion at a bottom of the opening.

By adopting the above-mentioned aspects, the effect that the protrusion is arranged at the bottom of the opening is provided. Scattering of incident light by the protrusion is assumed.

### Effects of the Invention

According to the present disclosure, it is possible to obtain an excellent effect of reducing reflection of incident light at the peripheral edge portion of the image sensor and preventing deterioration of the image quality.

### BRIEF DESCRIPTION OF DRAWINGS

FIG. 1 is a diagram showing a configuration example of an imaging apparatus according to an embodiment of the present disclosure.

FIG. 2 is a diagram showing a configuration example of an image sensor according to an embodiment of the present disclosure.

FIG. 3 is a plan view showing a configuration example of an image sensor according to an embodiment of the present disclosure.

FIG. 4 is a cross-sectional view showing a configuration example of an image sensor according to a first embodiment of the present disclosure.

FIG. 5 is a plan view showing a configuration example of protrusions according to the first embodiment of the present disclosure.

FIG. 6 is a diagram showing an example of reflection of incident light at the protrusion according to the first embodiment of the present disclosure.

FIG. 7 is a cross-sectional view showing another configuration example of the image sensor according to the first embodiment of the present disclosure.

FIG. 8 is a diagram showing an example of a method for manufacturing the image sensor according to the first embodiment of the present disclosure.

FIG. 9 is a diagram showing an example of a method for manufacturing the image sensor according to the first embodiment of the present disclosure.

FIG. 10 is a diagram showing an example of a method for manufacturing the image sensor according to the first embodiment of the present disclosure.

FIG. 11 is a diagram showing an example of a method for manufacturing the image sensor according to the first embodiment of the present disclosure.

FIG. 12 is a plan view showing a configuration example of protrusions according to a second embodiment of the present disclosure.

FIG. 13 is a plan view showing another configuration example of the protrusions according to the second embodiment of the present disclosure.

FIG. 14 is a diagram showing another configuration example of the protrusions according to the second embodiment of the present disclosure.

FIG. 15 is a plan view showing another configuration example of the protrusions according to the second embodiment of the present disclosure.

FIG. 16 is a cross-sectional view showing another configuration example of the protrusions according to the second embodiment of the present disclosure.

FIG. 17 is a diagram showing an example of a method for manufacturing the image sensor according to a third embodiment of the present disclosure.

FIG. 18 is a diagram showing another method for manufacturing the image sensor according to the third embodiment of the present disclosure.

FIG. 19 is a diagram showing another method for manufacturing the image sensor according to the third embodiment of the present disclosure.

FIG. 20 is a diagram showing another method for manufacturing the image sensor according to the third embodiment of the present disclosure.

FIG. 21 is a diagram showing another method for manufacturing the image sensor according to the third embodiment of the present disclosure.

FIG. 22 is a cross-sectional view showing a configuration example of an image sensor according to a fourth embodiment of the present disclosure.

FIG. 23 is a block diagram showing a schematic configuration example of a camera, which is an example of the imaging apparatus to which the present disclosure can be applied.

FIG. 24 is a diagram showing an example of a schematic configuration of an endoscopic surgery system.

FIG. 25 is a block diagram showing an example of a function configuration of a camera head and a CCU.

FIG. 26 is a block diagram showing an example of a schematic configuration of a vehicle control system.

FIG. 27 is an explanatory diagram showing an example of installation positions of a vehicle outside information detecting unit and an imaging unit.

### MODE FOR CARRYING OUT THE INVENTION

Next, modes for carrying out the present disclosure (hereinafter, referred to as embodiments) will be described with reference to the drawings. In the following drawings, the same or similar reference numerals are given to the same or similar parts. Furthermore, the embodiments will be described in the following order.

1. First embodiment

2. Second embodiment

3. Third embodiment

4. Fourth embodiment

5. Application examples to cameras

6.Application example to endoscopic surgery system

7. Application examples to mobile objects

### 1. First Embodiment

[Configuration of the Image Sensor]

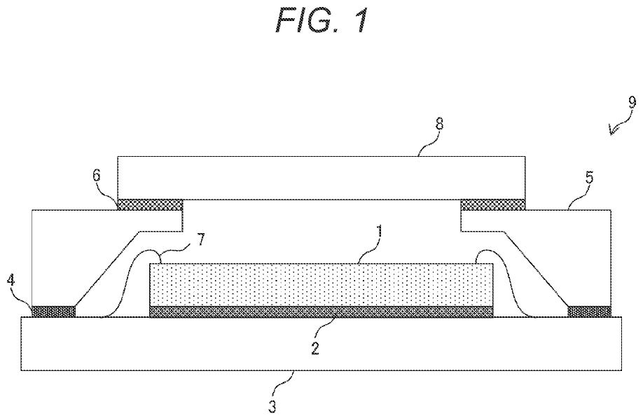

FIG. 1 is a diagram showing a configuration example of an imaging apparatus according to an embodiment of the present disclosure. An imaging apparatus 9 in the drawing includes an image sensor 1, a bonding wire 7, adhesives 2, 4, and 6, a circuit board 3, a frame 5, and a cover glass 8.

The image sensor 1 is a semiconductor element that converts incident light from a subject into an image signal. The image sensor 1 includes a semiconductor chip. As will be described later, the image sensor 1 is connected to the circuit board 3 by wire bonding.

The circuit board 3 is a board on which the image sensor 1 is mounted. An electronic circuit that processes the image signal generated by the image sensor 1 and controls the image sensor 1 can be arranged on the circuit board 3. The image sensor 1 is bonded to the circuit board 3 by the adhesive 2.

The bonding wire 7 electrically connects the image sensor 1 and the circuit board 3. The bonding wire 7 includes, for example, a wire of metal such as gold (Au), and is welded and connected to a bonding pad (not shown) arranged in each of the image sensor 1 and the circuit board 3. This connection can be made, for example, by the procedure described below. The bonding wire 7 is passed through an instrument called a capillary, and the tip of the bonding wire 7 is made spherical by electric discharge heating. Next, the tip of the bonding wire 7 is heat-pressed to the bonding pad using the capillary. Therefore, wire bonding can be performed.

Note that the connection strength by wire bonding can be evaluated according to the ball shear strength. Here, the ball shear strength is the shear strength of the bonding portion after connection, and can be measured by breaking (shearing) the connection portion with a dedicated inspection instrument.

The frame 5 is a housing that surrounds the image sensor 1. The frame 5 is bonded to the circuit board 3 by the adhesive 4. The cover glass 8 encloses the image sensor 1 and transmits incident light. The cover glass 8 is bonded to the frame 5 by the adhesive 6.

[Configuration of the Image Sensor]

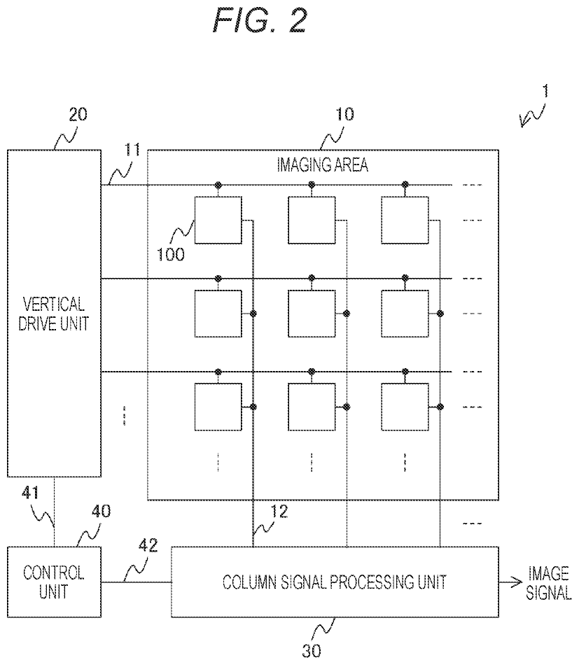

FIG. 2 is a diagram showing a configuration example of an image sensor according to an embodiment of the present disclosure. The image sensor 1 in the drawing includes an imaging area 10, a vertical drive unit 20, a column signal processing unit 30, and a control unit 40.

The imaging area 10 is an area in which pixels 100 are arranged in a two-dimensional grid pattern. Here, the pixel 100 generates an image signal depending on irradiation light. The pixel 100 has a photoelectric conversion unit that generates charges depending on the irradiation light. Furthermore, the pixel 100 further has a pixel circuit. This pixel circuit generates an image signal based on the charges generated by the photoelectric conversion unit. Generation of the image signal is controlled by a control signal generated by the vertical drive unit 20 described later. In the imaging area 10, signal lines 11 and 12 are arranged in an XY matrix pattern. The signal line 11 is a signal line that transmits a control signal for the pixel circuit in the pixel 100, is arranged for each row of the imaging area 10, and is commonly wired to the pixels 100 arranged in each row. The signal line 12 is a signal line that transmits an image signal generated by the pixel circuit of the pixel 100, is arranged for each column of the imaging area 10, and is commonly wired to the pixels 100 arranged in each column. These photoelectric conversion units and pixel circuits are formed on a semiconductor substrate.

The vertical drive unit 20 generates a control signal for the pixel circuit of the pixel 100. The vertical drive unit 20 transmits the generated control signal to the pixel 100 via the signal line 11 in the drawing. The column signal processing unit 30 processes the image signal generated by the pixel 100. The column signal processing unit 30 processes the image signal transmitted from the pixel 100 via the signal line 12 in the drawing. The processing in the column signal processing unit 30 corresponds to, for example, analog-to-digital conversion that converts an analog image signal generated in the pixel 100 into a digital image signal. The image signal processed by the column signal processing unit 30 is output as an image signal of the image sensor 1. The control unit 40 controls the entire image sensor 1. The control unit 40 controls the image sensor 1 by generating and outputting a control signal for controlling the vertical drive unit 20 and the column signal processing unit 30. The control signal generated by the control unit 40 is transmitted to the vertical drive unit 20 and the column signal processing unit 30 by signal lines 41 and 42, respectively.

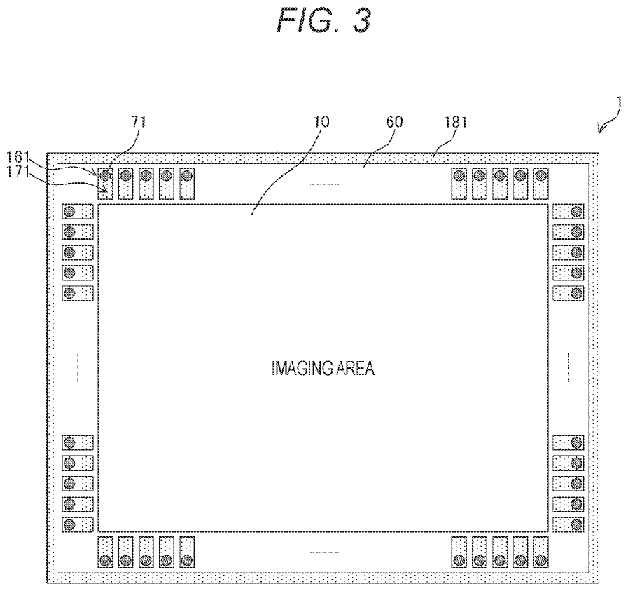

FIG. 3 is a plan view showing a configuration example of the image sensor according to the embodiment of the present disclosure. This drawing is a diagram showing the configuration of a light-receiving surface irradiated with incident light in the image sensor 1. On the light-receiving surface of the image sensor 1 in the drawing, the imaging area 10 described with reference to FIG. 2 is arranged at the center. A peripheral pad area 60 on which the bonding pad to which the bonding wire 7 is connected is arranged, is arranged around the imaging area 10. In the drawing, connection portions 71, which are a portion where the bonding wire 7 is connected to the bonding pad by wire bonding, are shown. As will be described later, the bonding pad is arranged in a deep part of the image sensor 1. Openings 161 that reach the bonding pad are formed on the light-receiving surface of the image sensor 1. Wire bonding is performed through the openings 161 to form the connection portions 71. Note that in the image sensor 1 in the drawing, openings 171 are arranged adjacent to the openings 161. The opening 171 is an opening into which the above-mentioned inspection instrument for ball shear strength is inserted.

A scribe area 181 is arranged around the peripheral pad area 60. The scribe area 181 is a groove-shaped opening arranged around the semiconductor chip constituting the image sensor 1. The image sensor 1 is obtained such that a plurality of image sensors is formed adjacent to each other on a semiconductor wafer and is cut and separated into individual pieces. The scribe area 181 is an area where a blade for cutting is caused to contact. By forming such openings, the resin layer arranged in the image sensor 1 can be removed, and cutting for separation into individual pieces can be easily performed.

In this way, the peripheral pad area 60 and the scribe area 181 are arranged on the peripheral edge portion of the image sensor 1.

[Configuration of the Cross-Section of the Image Sensor]

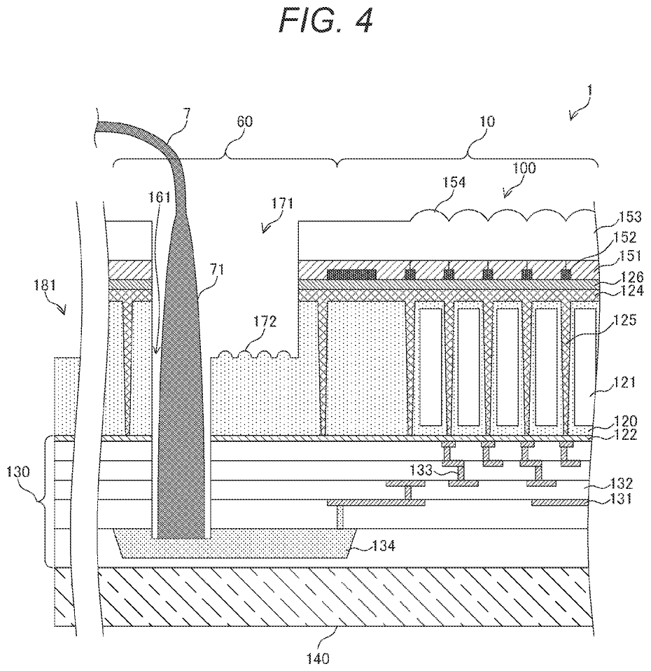

FIG. 4 is a cross-sectional view showing a configuration example of the image sensor according to the first embodiment of the present disclosure. This drawing is a diagram showing a configuration of the cross-section of the image sensor 1 at the imaging area 10, the peripheral pad area 60, and the scribe area 181. First, the configuration of the pixel 100 in the imaging area 10 will be described.

The image sensor 1 in the drawing includes a semiconductor substrate 120, a wiring area 130, a support substrate 140, protective films 122, 124, and 126, color filters 151, light shielding films 152, a planarizing film 153, and on-chip lenses 154.

The semiconductor substrate 120 is a semiconductor substrate on which semiconductor element portions such as the photoelectric conversion unit and the pixel circuit of the pixel 100, the vertical drive unit 20, and the like described with reference to FIG. 2 are arranged. The semiconductor substrate 120 can include, for example, silicon (Si). The semiconductor elements such as the photoelectric conversion unit and the like are formed in a well area formed in the semiconductor substrate 120. For the sake of convenience, it is assumed that the semiconductor substrate 120 in the drawing constitutes a p-type well area. Furthermore, in the drawing, the photoelectric conversion unit is described as an example of the semiconductor element. This photoelectric conversion unit is formed by a pn junction formed between an n-type semiconductor area 121 and a p-type well area around the n-type semiconductor area 121 in the drawing. This pn junction constitutes a photodiode and performs photoelectric conversion when irradiated with incident light. The n-type semiconductor area 121 is arranged for each pixel 100. The semiconductor substrate 120 can be formed to have a thickness of, for example, several μm to several tens of μm.

The protective film 122 is a film arranged on the front surface of the semiconductor substrate 120 to protect the semiconductor substrate 120. The protective film 122 can include, for example, silicon oxide (SiO2).

The protective film 124 is a film arranged on the back surface of the semiconductor substrate 120 to protect the semiconductor substrate 120. The protective film 124 can include an inorganic material such as SiO2 or silicon nitride (SiN) that transmits incident light. Furthermore, separation areas 125 are arranged between the pixels 100. The separation area 125 separates the adjacent pixels 100 from each other. The separation area 125 is arranged in a trench formed from the back surface side of the semiconductor substrate 120, can include the same material as the protective film 124, and can be formed at the same time as the protective film 124.

The protective film 126 is a film arranged on the back surface of the semiconductor substrate 120 adjacent to the protective film 124 to protect the semiconductor substrate 120. Furthermore, the protective film 126 further planarizes the back surface of the semiconductor substrate 120 on which the color filters 151 described later are formed. As the protective film 126, for example, a film including an organic material or an inorganic material that transmits incident light can be used. Note that the protective films 122, 124, and 126 are examples of the protective film described in the claims.

The wiring area 130 is an area in which wirings for transmitting a signal of the device of the pixel 100 such as the photoelectric conversion unit are formed. The wiring area 130 is arranged on the front surface side of the semiconductor substrate 120. Specifically, it is arranged adjacent to the protective film 122. The wiring area 130 is formed by stacking a wiring layer in which a wiring 131 is formed and an insulating layer 132 that insulates the wiring 131. The drawing shows an example of a wiring area including four stacked layers. The wirings 131 arranged in different layers are connected by via plugs 133. The wiring 131 can include, for example, a metal such as copper (Cu), tungsten (W), or the like. The insulating layer 132 can include, for example, SiO2. Furthermore, a bonding pad 134 described later is arranged in the wiring area 130.

The support substrate 140 is a substrate that is bonded to the wiring area 130 and supports the image sensor 1. The support substrate 140 is a substrate that increases the strength of the image sensor 1 in the step of manufacturing the image sensor 1.

The color filter 151 is an optical filter that transmits light having a predetermined wavelength within the incident light. The color filter 151 is arranged for each pixel 100. As the color filter 151, for example, a color filter 151 that transmits any of red light, green light, and blue light can be used. The light shielding film 152 is a film that shields the incident light. The light shielding film 152 is arranged at the boundary of the pixels 100 and shields light transmitted through the color filter 151 of the adjacent pixel 100. Therefore, color mixing can be prevented.

The planarizing film 153 is a film that planarizes the back surface of the semiconductor substrate 120 on which the on-chip lenses 154 described later are formed. The planarizing film 153 can include the same material as the on-chip lens 154.

The on-chip lens 154 is a lens that is arranged for each pixel 100 and collects the incident light on the photoelectric conversion unit.

As described above, the image sensor 1 in the drawing corresponds to a back-illuminated image sensor in which incident light is emitted from the back surface that is a surface different from the front surface that is a surface on which the wiring area 130 of the semiconductor substrate 120 is arranged.

Next, the peripheral pad area 60 will be described. The bonding pad 134 is arranged in the wiring area 130 of the peripheral pad area 60. Furthermore, the opening 161 that reaches the bonding pad 134 from the back surface of the image sensor 1 is formed. The bonding wire 7 is connected to the bonding pad 134 through the opening 161 to form the connection portion 71.

The opening 171 is arranged adjacent to the opening 161. The opening 171 opens from the planarizing film 153 and the protective films 124 and 126 to the area of the semiconductor substrate 120. An inspection instrument is inserted into this opening 171 to perform the ball shear strength. The ball shear strength is performed by shearing the connection portion 71 using the inspection instrument. Shearing of the connection portion 71 can be performed at a position of ¼ or less of the height of the connection portion 71 from the head of the connection portion 71. Therefore, the opening depth of the opening 171 can be made shallower than that of the opening 161.

Furthermore, protrusions 172 are arranged at the bottom of the opening 171. The protrusions 172 scatter the reflected light when the incident light is reflected at the bottom of the opening 171. Therefore, the influence of the reflected light in the opening 171 can be reduced. The details of the configuration of the protrusions 172 will be described later.

Similarly as in the pixel area 10, the separation area 125 is arranged in the semiconductor substrate 120 in the vicinity of the peripheral pad area 60. The separation area 125 in the peripheral pad area 60 is formed in a groove shape in the vicinity of the area where the bonding pad 134 is arranged to insulate the semiconductor substrate 120 in the peripheral pad area 60. Furthermore, the separation area 125 can eliminate the influence of the chipping of the semiconductor substrate 120 generated in the scribe area 181.

The scribe area 181 is arranged on an outer side of the peripheral pad area 60. The opening constituting the scribe area 181 can be formed at the same time as the openings 171.

[Arrangement of the Protrusions]

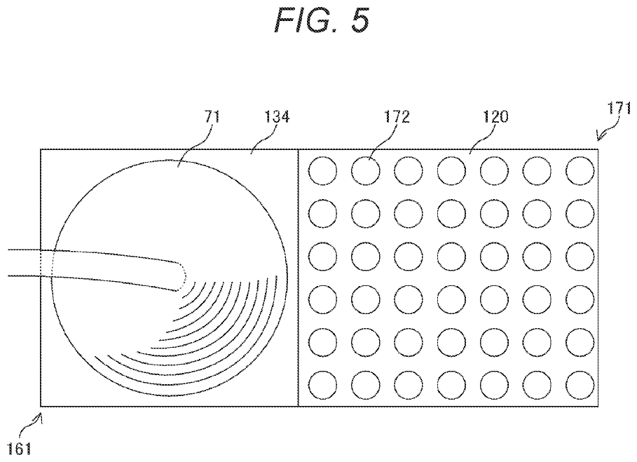

FIG. 5 is a plan view showing a configuration example of the protrusions according to the first embodiment of the present disclosure. The drawing is a diagram showing an arrangement example of the protrusions 172. In the opening 161 of the drawing, the bonding pad 134 is arranged at the bottom and the connection portion 71 of the bonding wire 7 is arranged. In the adjacent opening 171, the semiconductor substrate 120 is arranged at the bottom and a plurality of protrusions 172 is arranged at equal pitches. As shown in the drawing, the protrusions 172 can be formed in a circular shape. The height of the protrusions 172 can be, for example, 0.2 to 4 μm. Furthermore, the protrusions 172 can be arranged, for example, at a pitch of 1 to 6 μm.

[Effect of the Protrusions]

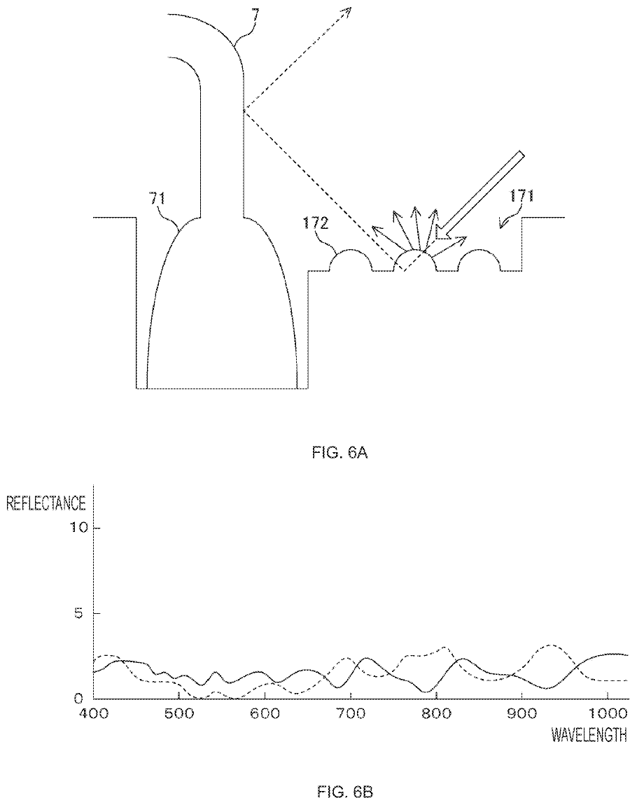

FIG. 6 is a diagram showing an example of reflection of incident light at the protrusion according to the first embodiment of the present disclosure. In the drawing, a is a diagram showing the scattering of the reflected light by the protrusion 172. In the drawing, the outline arrow represents the incident light, and the solid arrows represent the incident light reflected by the protrusion 172. As shown in the drawing, the reflected light is scattered by the protrusion 172. Therefore, it is possible to reduce the reflectance in a specific direction. Note that the dotted arrow represents the reflected light in a case where the protrusions 172 are not arranged. In a case where the protrusions 172 are not arranged, the incident light is reflected off the bottom of the opening 171 without being scattered and is further reflected by the bonding wire 7 to become stray light. This stray light is incident on the imaging area 10 and causes flare. Thus, in a case where the protrusions 172 are not arranged, for example, the reflectance in the direction toward the bonding wire 7 becomes high, and the influence of the reflected light in the direction becomes large. Specifically, strong flare is generated in the vicinity of the bonding wire 7, and the image quality is deteriorated.

In the drawing, b is a diagram showing the relationship between the wavelength of incident light and the reflectance in a case where the protrusions 172 are arranged at the bottom of the opening 171. In b of the drawing, the horizontal axis represents the wavelength of incident light. The unit is nm. Furthermore, in b of the drawing, the vertical axis represents the reflectance. The unit is %. Here, the reflectance represents the ratio of the reflected light having a reflection angle equal to the incident angle to the incident light regarding the reflection at the bottom of the opening 171. The solid line graph in b of the drawing shows the case where the incident angle is 60 degrees, and the dotted line graph shows the case where the incident angle is 30 degrees. It can be seen that the reflectance is less than 5% in each case. By arranging the protrusions 172 in this way, the influence of the reflected light at the bottom of the opening 171 can be reduced.

[Other Configuration of the Image Sensor]

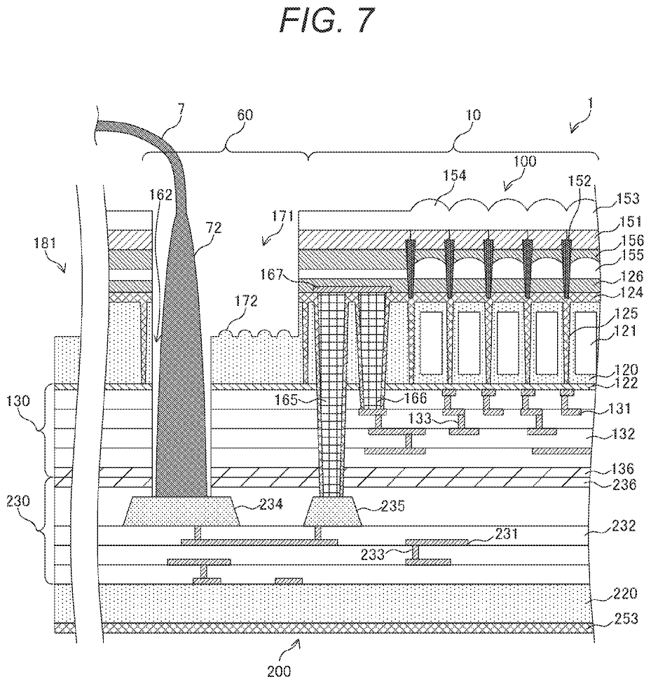

FIG. 7 is a cross-sectional view showing another configuration example of the image sensor according to the first embodiment of the present disclosure. In the image sensor 1 in the drawing, a substrate 200 is arranged instead of the support substrate 140. The substrate 200 is a substrate including a semiconductor substrate 220 and a wiring area 230. For example, a circuit other than the imaging area 10 described with reference to FIG. 2 can be arranged on the substrate 200. In this case, only the imaging area 10 is arranged on the semiconductor substrate 120. The wiring area 230 includes a wiring 231 and an insulating layer 232, and is bonded to the wiring area 130. Protective films 136 and 236 are arranged on the wiring areas 130 and 230 at the bonded surface, respectively. The protective films 136 and 236 can include, for example, SiN. Furthermore, a protective film 253 is arranged on the front surface of the semiconductor substrate 220.

Signal transmission between the wiring area 130 and the wiring area 230 can be performed via via plugs 165 and 166 and a wiring 167. The via plug 165 is a via plug formed through the semiconductor substrate 120 and the wiring area 130, and the via plug 166 is a via plug formed through the semiconductor substrate 120. Furthermore, the wiring 167 is a wiring formed in the protective film 126 on the back surface side of the semiconductor substrate 120 to electrically connect the via plugs 165 and 166.

The bonding wire 7 is connected to a bonding pad 234 arranged in the wiring area 230. An opening 162 that reaches the bonding pad 234 from the back surface of the image sensor 1 is formed. The bonding wire 7 is connected to the bonding pad 234 through the opening 162 to form a connection portion 72. The opening 171 is arranged adjacent to the opening 162, and the protrusions 172 are arranged at the bottom of the opening 171.

Note that the image sensor 1 in the drawing further includes in-layer lenses 155 and a planarizing film 156. The in-layer lenses 155 are a lens that is arranged in an inner layer of the image sensor 1 and collects the incident light. The in-layer lenses 155 can include, for example, SiN. The planarizing film 156 is a film that planarizes the surface of the in-layer lenses 155. This planarizing film 156 can include, for example, resin. Furthermore, the light shielding films 152 in the drawing are formed through the planarizing film 153, the in-layer lenses 155, and the protective film 126.

[Method for Manufacturing the Image Sensor]

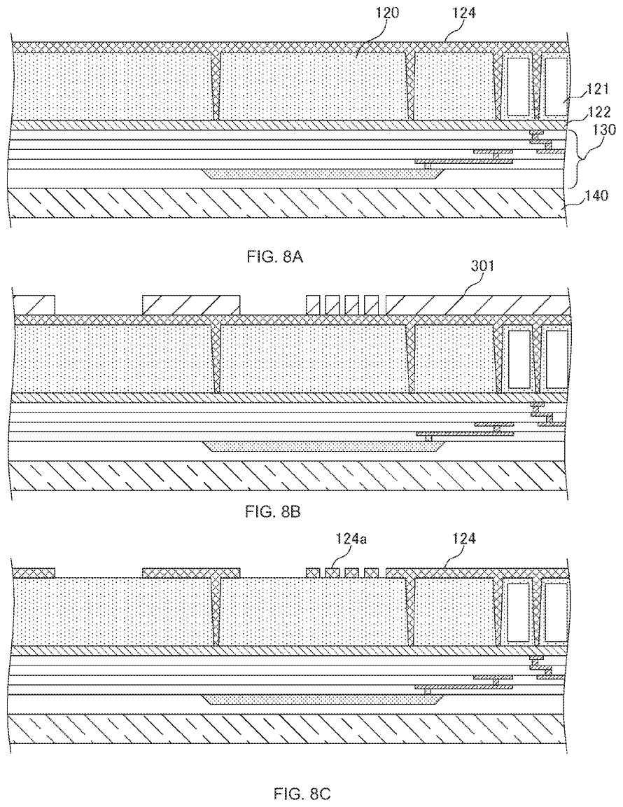

FIGS. 8 to 11 are diagrams showing an example of a method for manufacturing the image sensor according to the first embodiment of the present disclosure. FIGS. 8 to 11 are diagrams showing steps of manufacturing the image sensor 1 described with reference to FIG. 4.

First, the well area and the n-type semiconductor areas 121 are formed in the semiconductor substrate 120. This step corresponds to the imaging area forming step. Next, the protective film 122 is formed on the front surface of the semiconductor substrate 120, and the wiring area 130 is arranged adjacently. This step corresponds to the wiring area arranging step. Next, the support substrate 140 is bonded, and then the semiconductor substrate 120 is ground to reduce the thickness. Next, the protective film 124 is arranged. This step corresponds to the protective film arranging step (a in FIG. 8).

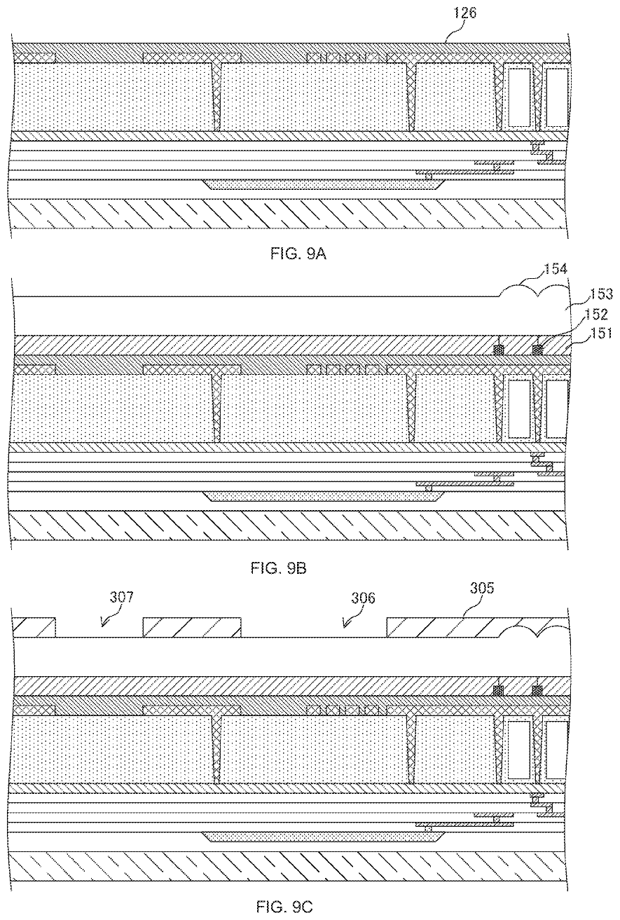

Next, a resist 301 is arranged on the surface of the protective film 124 and patterning is performed (b in FIG. 8). Next, the protective film 124 is etched using the resist 301 as a mask to form a patterned protective film 124a (c in FIG. 8). Next, the protective film 126 is arranged on the surface of the protective film 124 (d in FIG. 9), and the light shielding films 152, the color filters 151, and the planarizing film 153 are stacked in order. Next, the on-chip lenses 154 are formed on the surface of the planarizing film 153 (e in FIG. 9).

Next, a resist 305 is arranged on the surface of the on-chip lenses 154. In this resist 305, an opening 306 corresponding to the openings 161 and 171 described with reference to FIG. 4 and an opening 307 corresponding to the scribe area 181 are formed (f in FIG. 9).

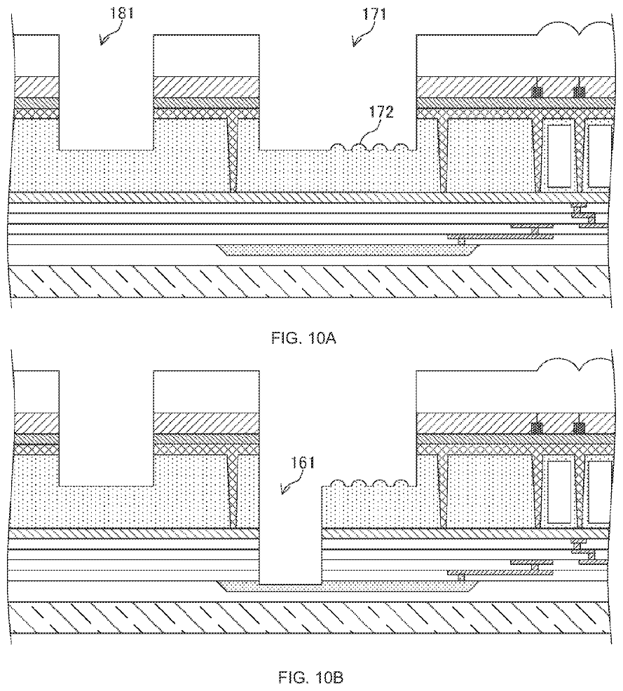

Next, the image sensor 1 is etched using the resist 305 as a mask. This etching is performed up to the area of the semiconductor substrate 120. Furthermore, the etching can be performed by dry etching. Therefore, the opening 171 and the scribe area 181 are formed. During this etching, a part of the opening 161 adjacent to the opening 171 is also formed. This step corresponds to the opening forming step. Furthermore, during this etching, the shape of the patterned protective film 124a described with reference to f in FIG. 9 is transferred to the semiconductor substrate 120 at the bottom of the opening 171 to form the protrusions 172 (g in FIG. 10). This is because the protective film 124a acts as a mask due to the difference in etching rate between the protective film 124a and the protective film 126, and the etching amount of the semiconductor substrate 120, which is a layer under the protective film 124a, is reduced. The step corresponds to the protrusion arranging step.

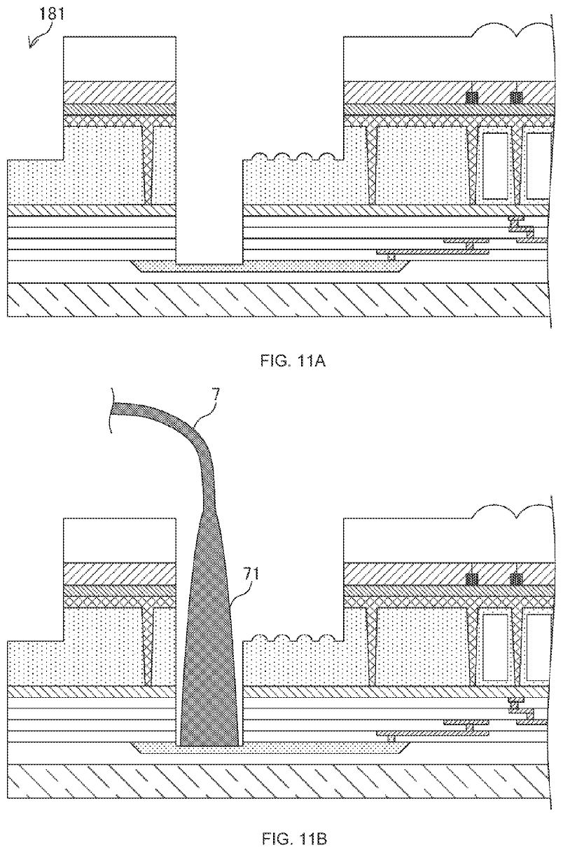

Next, the opening 161 is formed (h in FIG. 10). This can be formed by the step similar to that for the opening 171. Next, the semiconductor wafer is cut along the scribe area 181 and separated into individual pieces (i in FIG. 11). Next, the image sensor 1 is bonded to the circuit board 3 (not shown), and the bonding wire 7 is connected to perform wire bonding (j in FIG. 11). The image sensor 1 can be manufactured by the above steps.

As described above, in the image sensor 1 of the first embodiment of the present disclosure, the protrusions 172 are arranged in the opening in the vicinity of the connection portion 71 of the bonding wire 7, and the reflected light is scattered. Therefore, the reflection of the incident light at the peripheral edge portion of the image sensor 1 is reduced, and deterioration of the image quality can be prevented.

### 2. Second Embodiment

Although the image sensor 1 of the first embodiment described above uses the protrusions 172 having a hemispherical shape, it is also possible to use protrusions having a different shape.

[Configuration of the Protrusions]

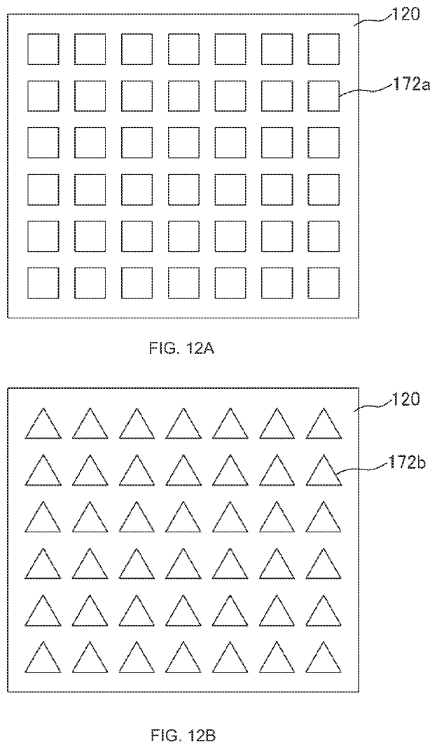

FIG. 12 is a plan view showing a configuration example of protrusions according to the second embodiment of the present disclosure. The drawing shows a variation of the planar shape of the protrusions 172. In the drawing, a represents an example of protrusions 172a having a rectangular shape. Furthermore, b in the drawing represents an example of protrusions 172b having a triangular shape. Note that the shape of the protrusions 172 may be another shape such as an octagon.

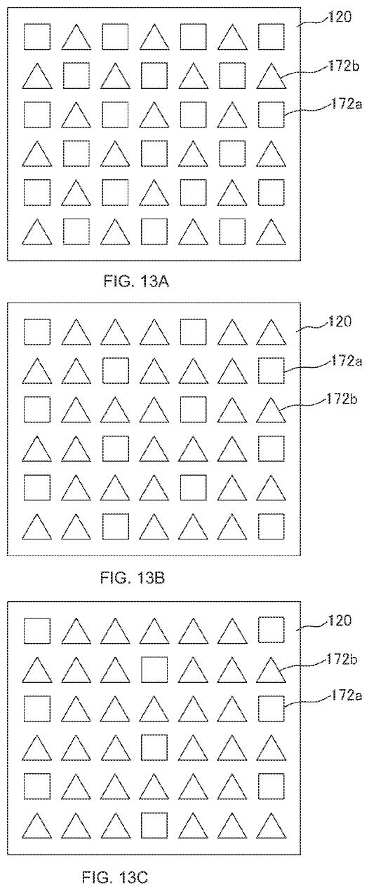

FIG. 13 is a plan view showing another configuration example of the protrusions according to the second embodiment of the present disclosure. The drawing shows an example in which the protrusions 172a and the protrusions 172b are arranged. In the drawing, a represents an example in which the protrusions 172a and the protrusions 172b are arranged alternately and arrayed at equal pitches.

On the other hand, b and c in the drawing represent examples in which the periodicity of the arrangement of the protrusions 172a and the protrusions 172b is changed by asymmetrically arranging the protrusions 172a and the protrusions 172b. By changing the periodicity, it is possible to prevent the occurrence of interference fringes due to reflected light and prevent deterioration of the image quality.

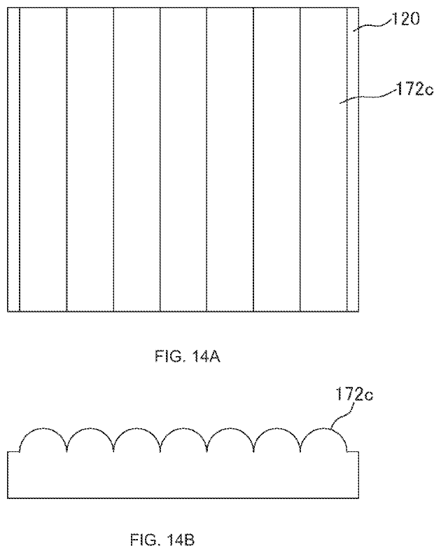

FIG. 14 is a diagram showing another configuration example of the protrusions according to the second embodiment of the present disclosure. In the drawing, a is a plan view showing a configuration example of the protrusions, and b in the drawing is a cross-sectional view showing a configuration example of the protrusions. The drawing shows an example in which a plurality of protrusions 172c formed in a semi-cylindrical shape is arrayed adjacent to each other. Here, the semi-cylindrical shape is a shape obtained by cutting a cylinder in half vertically.

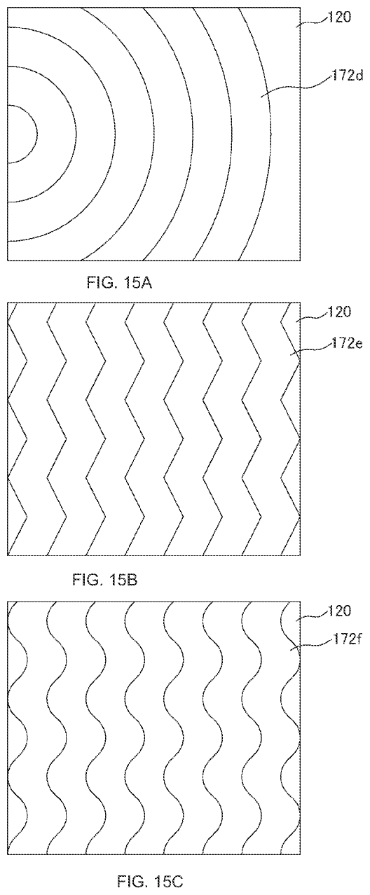

FIG. 15 is a plan view showing another configuration example of the protrusions according to the second embodiment of the present disclosure. In the drawing, a represents an example of protrusions 172d having a semi-cylindrical shape and arrayed concentrically. In the drawing, b represents an example of protrusions 172e having a semi-cylindrical cross-section and formed in a zigzag shape. In the drawing, c represents an example of protrusions 172f having a semi-cylindrical cross-section and formed in a wavy shape.

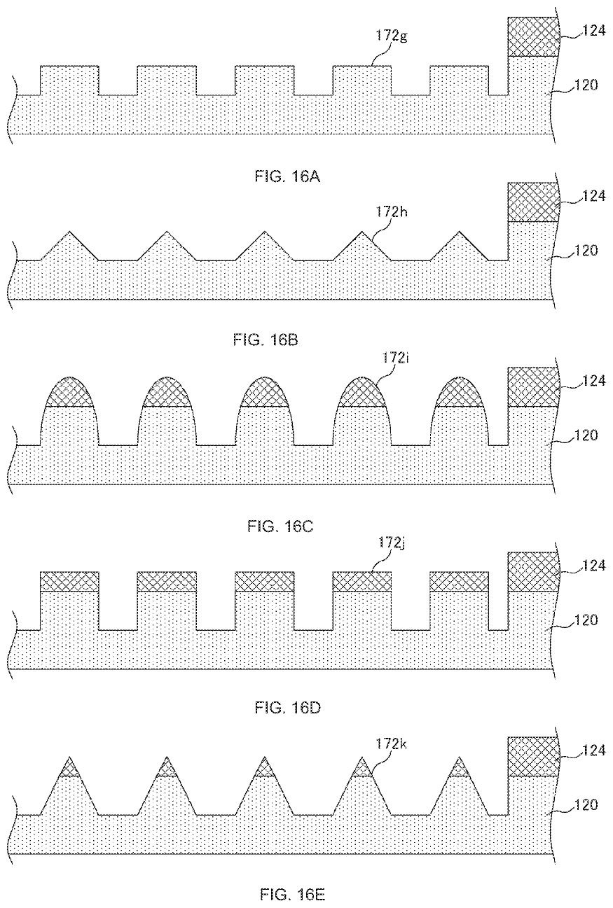

FIG. 16 is a cross-sectional view showing another configuration example of the protrusions according to the second embodiment of the present disclosure. In the drawing, a represents an example of protrusions 172g having a rectangular cross-section. In the drawing, b represents an example of protrusions 172h formed to be a triangular pyramid. In the drawing, c represents an example of protrusions 172i including the semiconductor substrate 120 and the protective film 124 and formed in a hemi-spherical shape. By stacking the semiconductor substrate 120 and the protective film 124 having different refractive indexes, the reflected light interferes with each other and is attenuated, so that the reflectance can be reduced. In the drawing, d represents an example of protrusions 172j including the semiconductor substrate 120 and the protective film 124 and formed to have a rectangular cross-section. In the drawing, e represents an example of protrusions 172k similarly formed in a triangular pyramid shape.

Since the other configurations of the image sensor 1 are similar to the configurations of the image sensor 1 described in the first embodiment of the present disclosure, the description thereof will be omitted.

As described above, the image sensor 1 of the second embodiment of the present disclosure can reduce the reflected light by using the protrusions 172a to 172k having shapes different from that of the protrusions 172.

### 3. Third Embodiment

In the image sensor 1 of the first embodiment described above, the shape of the patterned protective film 124a is transferred to the semiconductor substrate 120 at the bottom of the opening 171 to form the protrusions 172. On the other hand, in the third embodiment of the present disclosure, another method for manufacturing the protrusions 172 is proposed.

[Method for Manufacturing the Image Sensor]

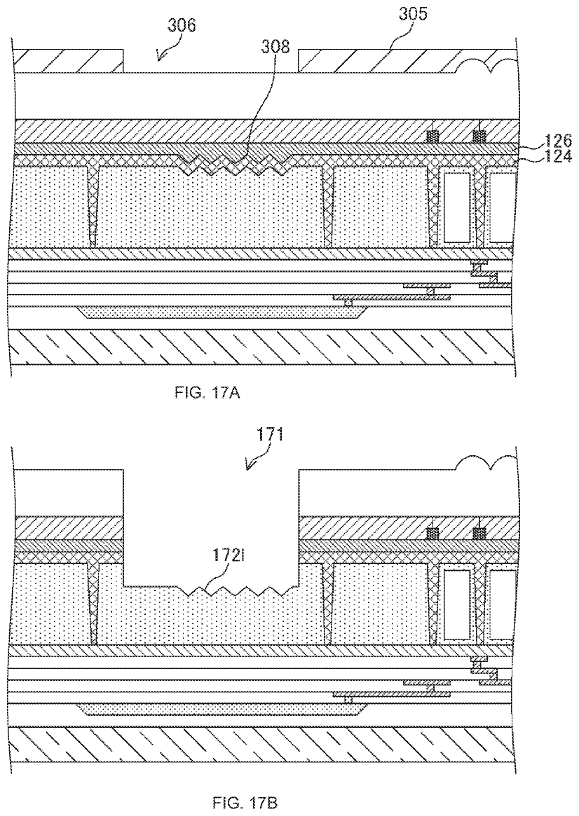

FIG. 17 is a diagram showing an example of a method for manufacturing the image sensor according to the third embodiment of the present disclosure. This drawing is a diagram corresponding to the steps of manufacturing the image sensor 1 described with reference to f in FIG. 9 and g in FIG. 10.

In f in the drawing, the back surface of the semiconductor substrate 120 is formed in a moth-eye shape by protrusions having a triangular pyramid shape. The protrusions can be formed by precipitating a 111 face by wet-etching a 100 face on the front surface of the semiconductor substrate 120. The shape of the protrusions is transferred to the protective film 124 stacked on the semiconductor substrate 120 and planarized by the protective film 126. Next, by etching for the opening 171, it is possible to form protrusions 172l to which the shape of the protrusions described above has been transferred (g in the drawing).

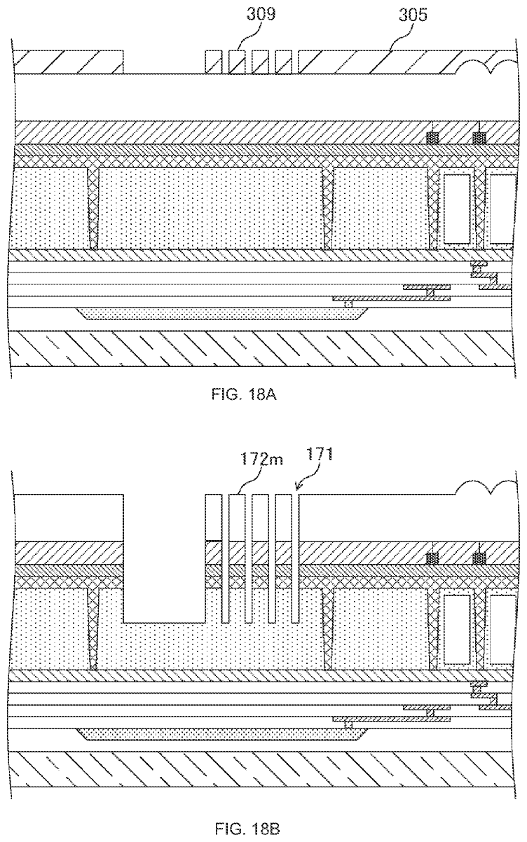

FIG. 18 is a diagram showing another method for manufacturing the image sensor according to the third embodiment of the present disclosure. In f in the drawing, when the resist 305 is arranged on the back surface of the image sensor 1, a resist 309 is arranged at the positions where the protrusions 172 are to be arranged. Next, protrusions 172m can be formed by performing etching using the resists 305 and 309 as masks (g in the drawing).

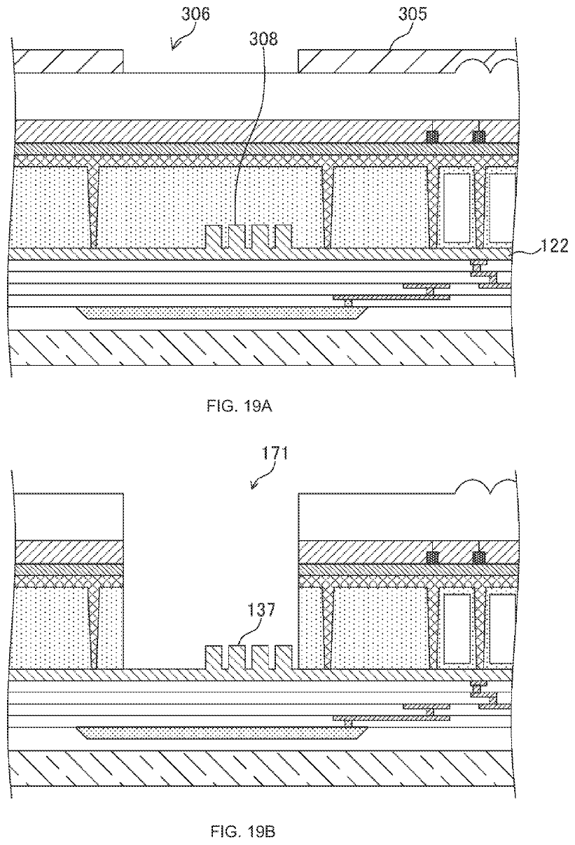

FIG. 19 is a diagram showing another method for manufacturing the image sensor according to the third embodiment of the present disclosure. In f in the drawing, recesses 308 are formed on the front surface of the semiconductor substrate 120 at the positions where the protrusions 172 are to be arranged, and the protective film 122 is embedded in the recesses 308. Next, by performing etching using the resist 305 as a mask, protrusions 137 including the protective film 122 can be formed (g in the drawing).

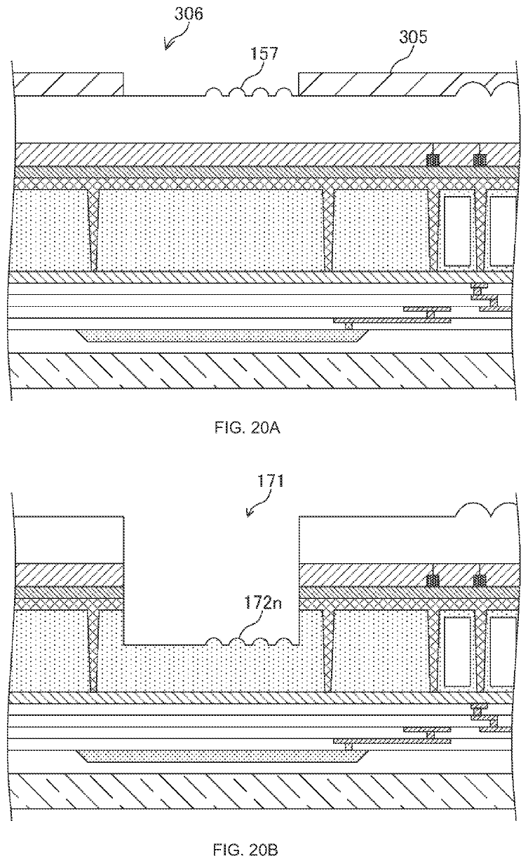

FIG. 20 is a diagram showing another method for manufacturing the image sensor according to the third embodiment of the present disclosure. In f in the drawing, on-chip lenses 157 are formed at the positions where the protrusions 172 are to be arranged. Next, by performing etching using the resist 305 as a mask, protrusions 172n obtained when the shape of the on-chip lenses 157 is transferred to the semiconductor substrate 120 can be formed (g in the drawing). Note that it may be configured such that the shape of the on-chip lenses 157 is transferred to the protective film 122 to form the protrusions.

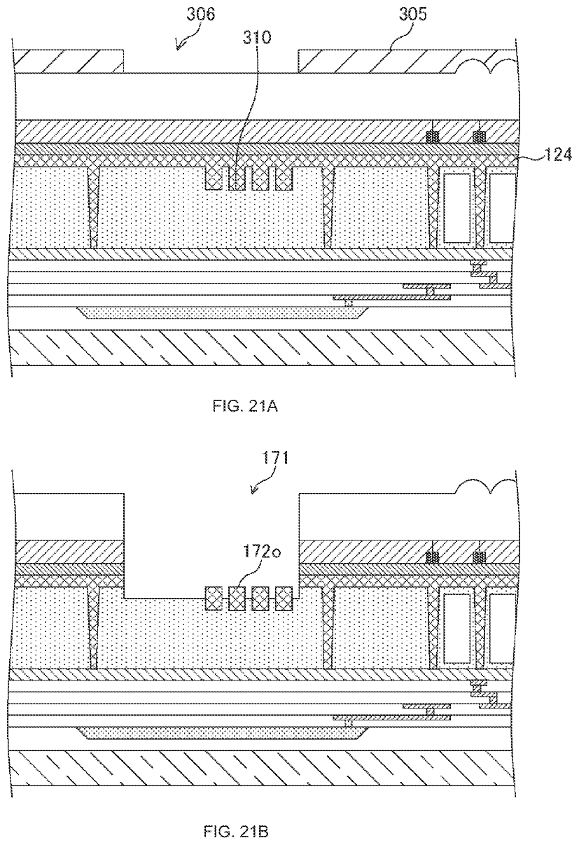

FIG. 21 is a diagram showing another method for manufacturing the image sensor according to the third embodiment of the present disclosure. In f in the drawing, recesses 310 are formed on the back surface of the semiconductor substrate 120 at the positions where the protrusions 172 are to be arranged, and the protective film 124 is embedded in the recesses 310. Next, by performing etching using the resist 305 as a mask, protrusions 172o including the protective film 122 can be formed (g in the drawing).

Since the other configurations of the image sensor 1 are similar to the configurations of the image sensor 1 described in the first embodiment of the present disclosure, the description thereof will be omitted.

As described above, the image sensor 1 of the third embodiment of the present disclosure can form the protrusions 172 using the manufacturing method different from that for the protrusions 172 described with reference to FIG. 3.

### 4. Fourth Embodiment

In the image sensor 1 of the first embodiment described above, the protrusions 172 are arranged in the opening in the vicinity of the connection portion 71 of the bonding wire 7. On the other hand, the image sensor 1 of the fourth embodiment of the present disclosure is different from the above-described first embodiment in that protrusions are arranged in the scribe area 181.

[Configuration of the Image Sensor]

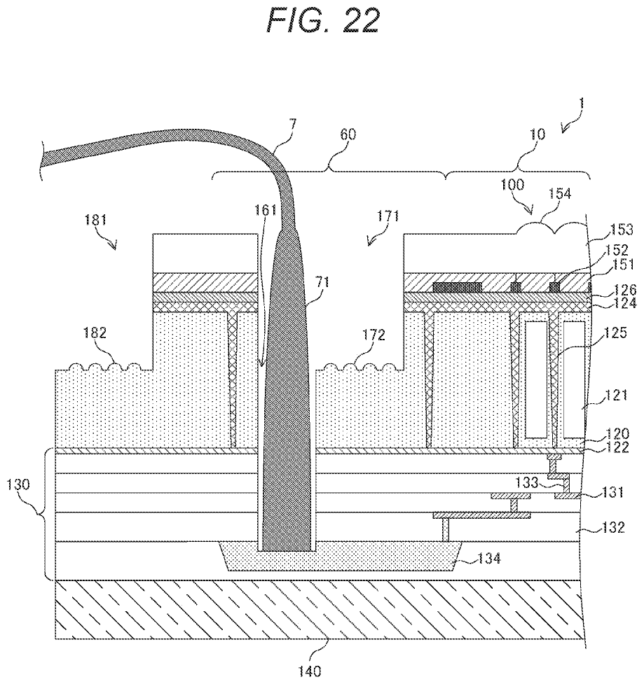

FIG. 22 is a cross-sectional view showing a configuration example of the image sensor according to the fourth embodiment of the present disclosure. The image sensor 1 in the drawing is different from the image sensor 1 described with reference to FIG. 4 in that protrusions 182 are further arranged at the bottom of the scribe area 181.

Similarly to the protrusions 172, the protrusions 182 are protrusions formed on the semiconductor substrate 120. By arranging the protrusions 182 in the scribe area 181, the reflected light can be scattered when the scribe area 181 is irradiated with the incident light. Since the scribe area 181 is also arranged in the vicinity of the bonding wire 7, stray light increases when the reflected light of the scribe area 181 is further reflected by the bonding wire 7. When this stray light is incident on the imaging area 10, the image quality deteriorates. However, by forming the protrusions 182 in the scribe area 181, the reflected light is scattered and the increase in stray light can be reduced.

Note that the configuration of the image sensor 1 is not limited to this example. For example, the protrusions 172 may be omitted. Further, a front-illuminated image sensor can also be used as the image sensor 1. [0088] Since the other configurations of the image sensor 1 are similar to the configurations of the image sensor 1 described in the first embodiment of the present disclosure, the description thereof will be omitted.

As described above, in the image sensor 1 of the fourth embodiment of the present disclosure, the reflected light in the scribe area 181 is scattered by arranging the protrusions 182. Therefore, the reflection of the incident light at the peripheral edge portion of the image sensor 1 is reduced, and deterioration of the image quality can be prevented.

5. Application Examples to Cameras

The technology according to the present disclosure (present technology) is applicable to a variety of products. For example, the present technology may be realized as an image sensor mounted in an imaging apparatus such as a camera.

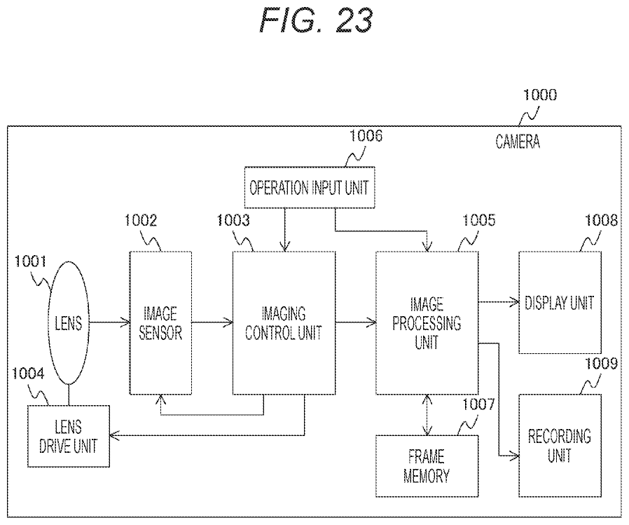

FIG. 23 is a block diagram showing a schematic configuration example of a camera, which is an example of the imaging apparatus to which the present technology can be applied. A camera 1000 in the drawing includes a lens 1001, an image sensor 1002, an imaging control unit 1003, a lens drive unit 1004, an image processing unit 1005, an operation input unit 1006, a frame memory 1007, a display unit 1008, and a recording unit 1009.

The lens 1001 is an imaging lens of the camera 1000. The lens 1001 collects light from a subject and makes it incident on the image sensor 1002 described later to form an image of the subject.

The image sensor 1002 is a semiconductor element that captures an image of the light from the subject collected by the lens 1001. The image sensor 1002 generates an analog image signal according to the illuminated light, converts it into a digital image signal, and outputs it.

The imaging control unit 1003 controls imaging by the image sensor 1002. The imaging control unit 1003 controls the image sensor 1002 by generating a control signal and outputting the control signal to the image sensor 1002. Furthermore, the imaging control unit 1003 can perform autofocus in the camera 1000 on the basis of the image signal output from the image sensor 1002. Here, the autofocus is a system that detects the focal position of the lens 1001 and automatically adjusts it. As this autofocus, a method for detecting an image plane phase difference using a phase difference pixel arranged in the image sensor 1002 and detecting the focal position (image plane phase difference autofocus) can be used. Furthermore, it is also possible to apply a method (contrast autofocus) of detecting the position where the contrast of the image is the highest as the focal position. The imaging control unit 1003 adjusts the position of the lens 1001 via the lens drive unit 1004 on the basis of the detected focal position, and performs autofocus. Note that the imaging control unit 1003 can be configured by, for example, a digital signal processor (DSP) equipped with firmware.

The lens drive unit 1004 drives the lens 1001 on the basis of the control of the imaging control unit 1003. The lens drive unit 1004 can drive the lens 1001 by changing the position of the lens 1001 using a built-in motor.

The image processing unit 1005 processes the image signal generated by the image sensor 1002. This processing corresponds to, for example, demosaicing for generating an image signal of a missing color among image signals corresponding to red, green, and blue for each pixel, noise reduction for removing noise of the image signal, encoding of the image signal, and the like. The image processing unit 1005 can be configured by, for example, a microcomputer equipped with firmware.

The operation input unit 1006 receives an operation input from the user of the camera 1000. As the operation input unit 1006, for example, a push button or a touch panel can be used. The operation input received by the operation input unit 1006 is transmitted to the imaging control unit 1003 or the image processing unit 1005. Thereafter, processing corresponding to the operation input, for example, processing such as imaging of the subject or the like is started.

The frame memory 1007 is a memory that stores a frame that is an image signal for one screen. The frame memory 1007 is controlled by the image processing unit 1005 and holds a frame in the process of image processing.

The display unit 1008 displays the image processed by the image processing unit 1005. A liquid crystal panel can be used for the display unit 1008, for example.

The recording unit 1009 records the image processed by the image processing unit 1005. For the recording unit 1009, for example, a memory card or a hard disk can be used.

The camera to which the present invention can be applied has been described above. The present technology can be applied to the image sensor 1002 among the configurations described above. Specifically, the imaging apparatus 9 described with reference to FIG. 1 can be applied to the image sensor 1002. By applying the imaging apparatus 9 to the image sensor 1002, it is possible to reduce the occurrence of flare and the like, and it is possible to prevent deterioration of the image quality of the image generated by the camera 1000.

Note that although the camera has been described as an example here, the technique according to the present invention may be applied to, for example, a monitoring apparatus.

### 6. Application Example to Endoscopic Surgery System

The technology according to the present disclosure is applicable to a variety of products. For example, the technology according to the present disclosure may be applied to an endoscopic surgery system.

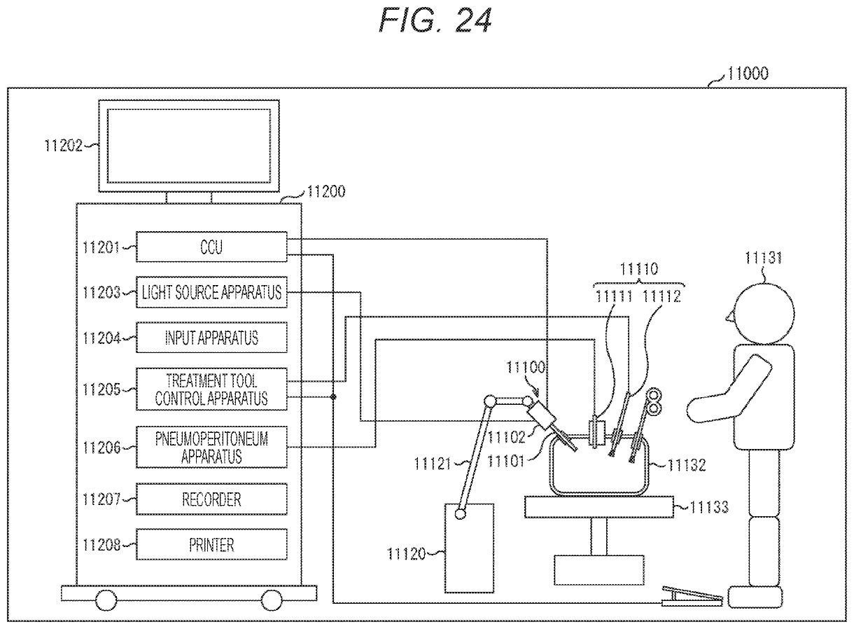

FIG. 24 is a diagram showing an example of a schematic configuration of an endoscopic surgery system to which the technology according to the present disclosure can be applied.

FIG. 24 shows a situation where an operator (doctor) 11131 is performing surgery on a patient 11132 on a patient bed 11133 using the endoscopic surgery system 11000. As shown, the endoscopic surgery system 11000 includes an endoscope 11100, other surgical tools 11110, e.g., a pneumoperitoneum tube 11111, an energy treatment tool 11112, or the like, a support arm apparatus 11120 supporting the endoscope 11100, and a cart 11200 on which various apparatuses for an endoscopic surgery are mounted.

The endoscope 11100 includes a lens tube 11101 in which an area with a predetermined length from a tip end, is inserted into the body cavity of the patient 11132, and a camera head 11102 connected to a base end of the lens tube 11101. In the example shown, the endoscope 11100 configured as a so-called rigid scope including a rigid lens tube 11101, is shown, but the endoscope 11100 may be configured as a so-called flexible scope including a flexible lens tube.

An opening portion into which an objective lens is fitted, is provided on the tip end of the lens tube 11101. A light source apparatus 11203 is connected to the endoscope 11100, and light generated by the light source apparatus 11203 is guided to the tip end of the lens tube by a light guide provided to extend in the lens tube 11101, and is emitted towards an observation target in the body cavity of the patient 11132 through the objective lens. Note that the endoscope 11100 may be a forward-viewing endoscope, or may be an oblique-viewing endoscope or a side-viewing endoscope.

In the camera head 11102, an optical system and an image sensor are provided, and reflected light (observation light) from the observation target is condensed in the image sensor by the optical system. The observation light is subjected to the photoelectric conversion by the image sensor, and an electrical signal corresponding to the observation light, that is, an image signal corresponding to an observation image, is generated. The image signal is transmitted to a camera control unit (CCU) 11201, as RAW data.

The CCU 11201 includes a central processing unit (CPU), a graphics processing unit (GPU), or the like, and integrally controls the operation of the endoscope 11100 and the display apparatus 11202. Moreover, the CCU 11201 receives the image signal from the camera head 11102 and performs various image processing for displaying the image based on the image signal, for example, as development processing (demosaic processing) or the like, on the image signal.

The display apparatus 11202 displays an image based on the image signal subjected to the image processing by the CCU 11201 according to the control from the CCU 11201.

The light source apparatus 11203, for example, includes a light source such as a light emitting diode (LED), and supplies irradiation light at the time of capturing the surgical site or the like to the endoscope 11100.

The input apparatus 11204 is an input interface with respect to the endoscopic surgery system 11000. The user is capable of performing the input of various information items, or the input of an instruction with respect to endoscopic surgery system 11000, through the input apparatus 11204. For example, the user inputs an instruction or the like to change conditions of imaging (type of irradiation light, magnification, focal length, and the like) by the endoscope 11100.

The treatment tool control apparatus 11205 controls the driving of the energy treatment tool 11112 for the cauterization and the incision of the tissue, the sealing of the blood vessel, or the like. In order to ensure a visual field of the endoscope 11100 and to ensure a working space of the surgery operator, the pneumoperitoneum apparatus 11206 sends gas into the body cavity through the pneumoperitoneum tube 11111 such that the body cavity of the patient 11132 is inflated. The recorder 11207 is an apparatus capable of recording various information items associated with the surgery. The printer 11208 is an apparatus capable of printing various information items associated with the surgery, in various formats such as a text, an image, or a graph.

Note that the light source apparatus 11203 that supplies irradiation light in capturing the surgical site to the endoscope 11100 can be configured from, for example, a white light source configured by an LED, a laser light source, or a combination thereof. In a case where the white light source includes a combination of RGB laser light sources, it is possible to control an output intensity and an output timing of each color (each wavelength) with high accuracy, and thus, it is possible to adjust a white balance of the captured image with the light source apparatus 11203. Furthermore, in this case, laser light from each of the RGB laser light sources is emitted to the observation target in a time division manner, and the driving of the image sensor of the camera head 11102 is controlled in synchronization with the emission timing, and thus, it is also possible to capture an image corresponding to each of RGB in a time division manner. According to such a method, it is possible to obtain a color image without providing a color filter in the image sensor.

Furthermore, the driving of the light source apparatus 11203 may be controlled such that the intensity of the light to be output is changed for each predetermined time. The driving of the image sensor of the camera head 11102 is controlled in synchronization with a timing when the intensity of the light is changed, images are acquired in a time division manner, and the images are synthesized, and thus, it is possible to generate an image of a high dynamic range, without so-called black defects and overexposure.

Furthermore, the light source apparatus 11203 may be configured to supply light of a predetermined wavelength band corresponding to special light imaging. In the special light imaging, for example, light of a narrow band (i.e., white light) is applied, compared to irradiation light at the time of performing usual observation by using wavelength dependency of absorbing light in the body tissue, and thus, so-called narrow band imaging of capturing a predetermined tissue such as a blood vessel in a superficial portion of a mucous membrane with a high contrast, is performed. Alternatively, in the special light imaging, fluorescent light imaging of obtaining an image by fluorescent light generated by being irradiated with excited light, may be performed. In the fluorescent light imaging, for example, the body tissue is irradiated with the excited light, and the fluorescent light from the body tissue is observed (autofluorescent light imaging), or a reagent such as indocyanine green (ICG) is locally injected into the body tissue, and the body tissue is irradiated with excited light corresponding to a fluorescent light wavelength of the reagent, and thus, a fluorescent image is obtained. The light source apparatus 11203 can be configured to supply the narrow band light and/or the excited light corresponding to such special light imaging.

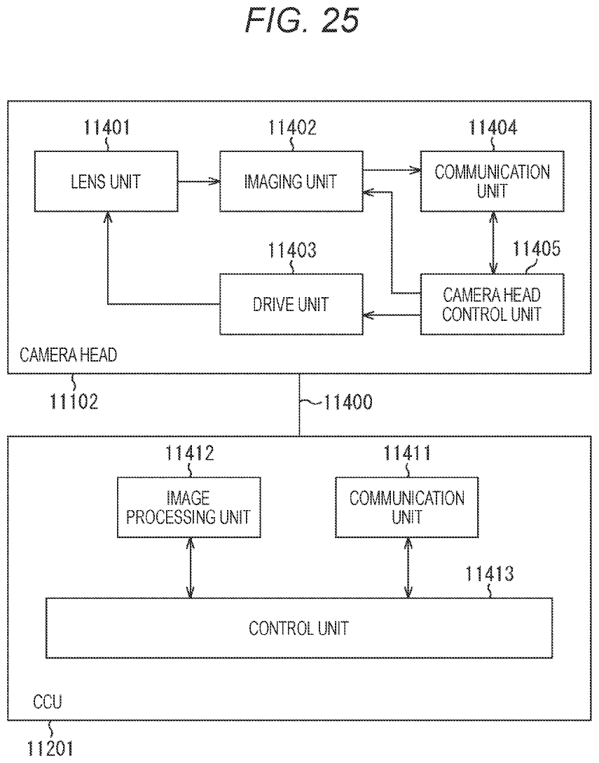

FIG. 25 is a block diagram showing an example of a functional configuration of the camera head 11102 and the CCU 11201 shown in FIG. 24.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are connected to be capable of mutual communication through a transmission cable 11400.

The lens unit 11401 is an optical system provided in a connection portion with the lens tube 11101. Observation light incorporated from a tip end of the lens tube 11101 is guided to the camera head 11102 and is incident on the lens unit 11401. The lens unit 11401 includes a combination of a plurality of lenses including a zoom lens and a focus lens.

The imaging unit 11402 includes an image sensor. The image sensor constituting the imaging unit 11402 may be one (so-called single plate type) or plural (so-called multi-plate type). In a case where the imaging unit 11402 is configured as a multi-plate type, for example, image signals each corresponding to RGB may be generated by each image sensor, and a color image may be obtained by combining them. Alternatively, the imaging unit 11402 may include a pair of image sensors for respectively acquiring right-eye and left-eye image signals corresponding to 3D (dimensional) display. The 3D display is performed, and thus, the operator 11131 is capable of more accurately grasping the depth of the biological tissue in the surgery portion. Note that, in a case where configuration of the imaging unit 11402 is of a multi-plate type, a plurality of lens units 11401 may be provided corresponding to each of the image sensors.

Furthermore, the imaging unit 11402 may not be necessarily provided in the camera head 11102. For example, the imaging unit 11402 may be provided immediately after the objective lens, in the lens tube 11101.

The drive unit 11403 includes an actuator, and moves the zoom lens and the focus lens of the lens unit 11401 along the optical axis by a predetermined distance, according to the control from the camera head control unit 11405. Therefore, it is possible to suitably adjust the magnification and the focal point of the image captured by the imaging unit 11402.

The communication unit 11404 includes a communication apparatus for transmitting and receiving various information items with respect to the CCU 11201. The communication unit 11404 transmits the image signal obtained from the imaging unit 11402 to the CCU 11201 through the transmission cable 11400, as the RAW data.

Furthermore, the communication unit 11404 receives a control signal for controlling the driving of the camera head 11102 from the CCU 11201 and supplies the control signal to the camera head control unit 11405. The control signal, for example, includes information associated with the imaging conditions, such as information of designating a frame rate of the captured image, information of designating an exposure value at the time of the imaging, and/or information of designating the magnification and the focal point of the captured image.

Note that the imaging conditions such as the frame rate, exposure value, magnification, and focal point described above may be appropriately designated by the user, or may be automatically set by the control unit 11413 of the CCU 11201 on the basis of the acquired image signal. In the latter case, a so-called auto exposure (AE) function, an auto focus (AF) function, and an auto white balance (AWB) function are provided in the endoscope 11100.

The camera head control unit 11405 controls the driving of the camera head 11102 on the basis of the control signal from the CCU 11201 received through the communication unit 11404.

The communication unit 11411 includes a communication apparatus for transmitting and receiving various information items with respect to the camera head 11102. The communication unit 11411 receives the image signal to be transmitted from the camera head 11102, through the transmission cable 11400.

Furthermore, the communication unit 11411 transmits the control signal for controlling the driving of the camera head 11102 to the camera head 11102. The image signal and the control signal can be transmitted by electrical communication, optical communication, or the like.

The image processing unit 11412 performs various image processing on the image signal which is the RAW data transmitted from the camera head 11102.

The control unit 11413 performs various types of control related to imaging of the surgical site or the like by the endoscope 11100 and display of a captured image obtained by imaging of the surgical site or the like. For example, the control unit 11413 generates the control signal for controlling the driving of the camera head 11102.

Furthermore, the control unit 11413 causes the display apparatus 11202 to display the captured image of the surgery site or the like on the basis of the image signal subjected to the image processing by the image processing unit 11412. At this time, the control unit 11413 may recognize various objects in the captured image by using various image recognition technologies. For example, the control unit 11413 detects the shape, the color, or the like of the edge of the object included in the captured image, and thus, it is possible to recognize a surgical tool such as forceps, a specific biological portion, bleed, mist at the time of using the energy treatment tool 11112, and the like When the captured image is displayed on the display apparatus 11202, the control unit 11413 may display various surgery support information items to be superimposed on the image of the surgery site, by using a recognition result. Surgery support information is displayed in a superimposed manner and presented to the operator 11131, thereby reducing the burden on the operator 11131 and allowing the operator 11131 to proceed with surgery reliably.

The transmission cable 11400 connecting the camera head 11102 and the CCU 11201 is an electrical signal cable corresponding to the communication of the electrical signal, an optical fiber corresponding to the optical communication, or a composite cable thereof.

Here, in the example shown, the communication is performed in a wired manner, by using the transmission cable 11400, but the communication between the camera head 11102 and the CCU 11201 may be performed in a wireless manner.

An example of the endoscopic surgery system to which the technology according to the present disclosure can be applied, has been described. The technology according to the present disclosure can be applied to the imaging unit 11402 among the configurations described above. Specifically, the imaging apparatus 9 described with reference to FIG. 1 can be applied to the imaging unit 10402. By applying the technology according to the present disclosure to the imaging unit 10402, a clearer operative image can be obtained, so that the operator can reliably confirm the surgical site.

Note that, here, although an endoscopic surgery system has been described as an example, the technology according to the present disclosure may be applied to, for example, a microscope surgery system and the like.

### 7. Application Examples to Mobile Objects

The technology according to the present disclosure is applicable to a variety of products. For example, the technology according to the present disclosure may be implemented as apparatuses mounted on any type of movable objects such as automobiles, electric vehicles, hybrid electric vehicles, motorcycles, bicycles, personal mobilities, airplanes, drones, ships, or robots.

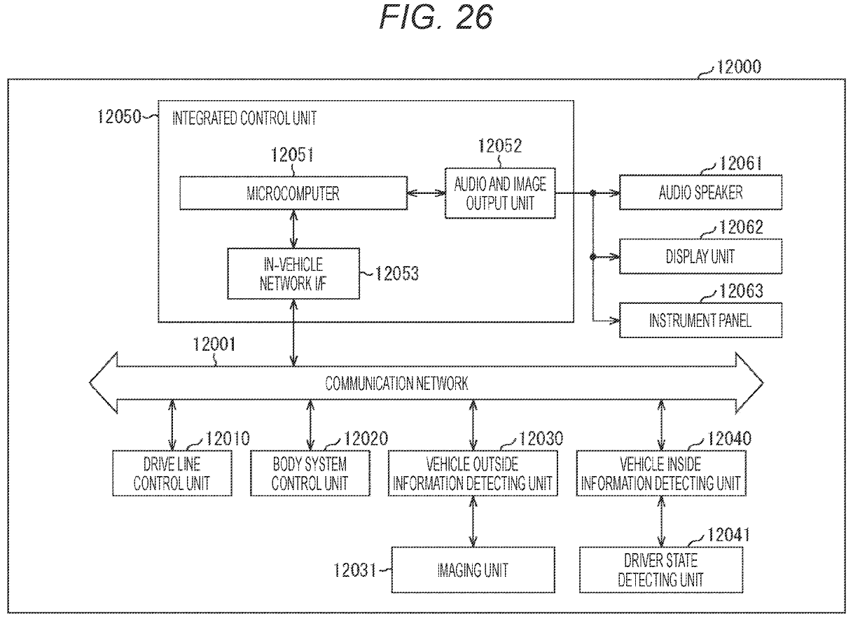

FIG. 26 is a block diagram showing a schematic configuration example of a vehicle control system, which is an example of a movable object control system to which the technology according to the present disclosure can be applied.

A vehicle control system 12000 includes a plurality of electronic control units connected via a communication network 12001. In the example shown in FIG. 26, the vehicle control system 12000 includes a drive line control unit 12010, a body system control unit 12020, a vehicle outside information detecting unit 12030, a vehicle inside information detecting unit 12040, and an integrated control unit 12050. Furthermore, a microcomputer 12051, an audio and image output unit 12052, and an in-vehicle network interface (I/F) 12053 are shown as functional configurations of the integrated control unit 12050.

The drive line control unit 12010 controls the operation of apparatuses related to the drive line of the vehicle in accordance with a variety of programs. For example, the drive line control unit 12010 functions as a control apparatus for a driving force generating apparatus such as an internal combustion engine or a driving motor that generates the driving force of the vehicle, a driving force transferring mechanism that transfers the driving force to wheels, a steering mechanism that adjusts the steering angle of the vehicle, a braking apparatus that generates the braking force of the vehicle, and the like.

The body system control unit 12020 controls the operations of a variety of apparatuses attached to the vehicle body in accordance with a variety of programs. For example, the body system control unit 12020 functions as a control apparatus for a keyless entry system, a smart key system, a power window apparatus, or a variety of lights such as a headlight, a backup light, a brake light, a blinker, or a fog lamp. In this case, the body system control unit 12020 can receive radio waves transmitted from a portable device that serves instead of the key or signals of a variety of switches. The body system control unit 12020 accepts input of these radio waves or signals, and controls the door lock apparatus, the power window apparatus, the lights, or the like of the vehicle.

The vehicle outside information detecting unit 12030 detects information regarding the outside of the vehicle including the vehicle control system 12000. For example, an imaging unit 12031 is connected to the vehicle outside information detecting unit 12030. The vehicle outside information detecting unit 12030 causes the imaging unit 12031 to capture images of the outside of the vehicle, and receives the captured image. The vehicle outside information detecting unit 12030 may perform processing of detecting an object such as a person, a car, an obstacle, a traffic sign, or a letter on a road, or processing of detecting the distance on the basis of the received image.

The imaging unit 12031 is an optical sensor that receives light and outputs an electric signal corresponding to the amount of received light. The imaging unit 12031 can output the electric signal as the image or output the electric signal as ranging information. Furthermore, the light received by the imaging unit 12031 may be visible light or invisible light such as infrared rays.

The vehicle inside information detecting unit 12040 detects information of the inside of the vehicle. The vehicle inside information detecting unit 12040 is connected, for example, to a driver state detecting unit 12041 that detects the state of the driver. The driver state detecting unit 12041 includes, for example, a camera that captures an image of a driver, and the vehicle inside information detecting unit 12040 may compute the degree of the driver's tiredness or the degree of the driver's concentration or determine whether or not the driver has a doze, on the basis of detection information input from the driver state detecting unit 12041.

The microcomputer 12051 can calculate a control target value of the driving force generating apparatus, the steering mechanism, or the braking apparatus on the basis of information regarding the inside and outside of the vehicle acquired by the vehicle outside information detecting unit 12030 or the vehicle inside information detecting unit 12040, and output a control command to the drive line control unit 12010. For example, the microcomputer 12051 can perform cooperative control for the purpose of executing the functions of the advanced driver assistance system (ADAS) including vehicle collision avoidanceor impact reduction, follow-up driving based on the inter-vehicle distance, constant vehicle speed driving, vehicle collision warning, vehicle lane deviation warning, or the like.

Furthermore, the microcomputer 12051 can perform cooperative control for the purpose of automatic driving or the like for autonomous running without depending on the driver's manipulation through control of the driving force generating apparatus, the steering mechanism, the braking apparatus, or the like on the basis of information around the vehicle acquired by the vehicle outside information detecting unit 12030 or the vehicle inside information detecting unit 12040.

Furthermore, the microcomputer 12051 can output a control command to the body system control unit 12020 on the basis of the information outside the vehicle obtained by the vehicle outside information detecting unit 12030. For example, the microcomputer 12051 can perform cooperative control for realizing glare protection such as controlling the headlight according to a position of a preceding vehicle or an oncoming vehicle detected by the vehicle outside information detecting unit 12030 to switch a high beam to a low beam.

The audio and image output unit 12052 transmits an output signal of at least one of a sound or an image to an output apparatus capable of visually or aurally notifying a passenger of the vehicle or the outside of the vehicle of information. In the example of FIG. 26, an audio speaker 12061, a display unit 12062, and an instrument panel 12063 are exemplified as the output apparatus. For example, the display unit 12062 may include at least one of an onboard display or a head-up display.

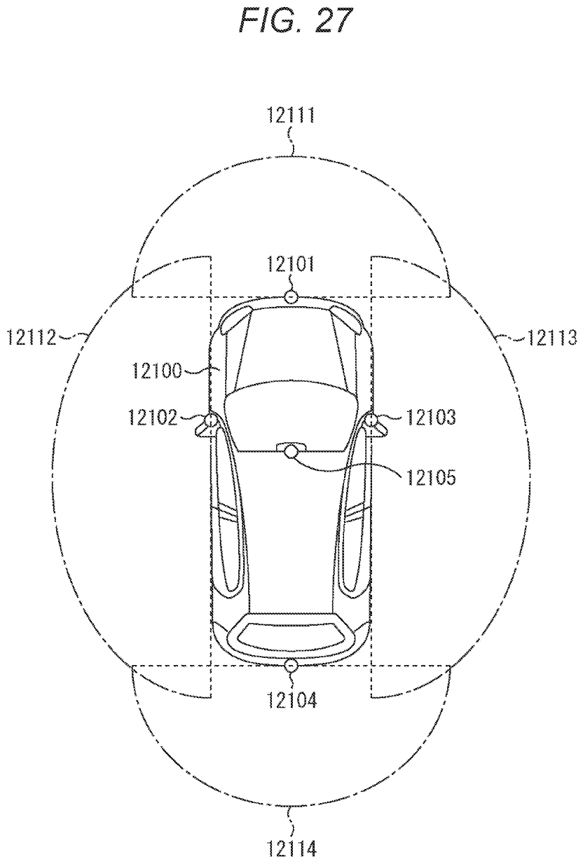

FIG. 27 is a diagram showing an example of an installation position of the imaging unit 12031.

In FIG. 27, a vehicle 12100 includes imaging units 12101, 12102, 12103, 12104, and 12105 as the imaging unit 12031.

The imaging units 12101, 12102, 12103, 12104, and 12105 are positioned, for example, at the front nose, the side mirror, the rear bumper, the back door, the upper part of the windshield in the vehicle compartment, or the like of a vehicle 12100. The imaging unit 12101 attached to the front nose and the imaging unit 12105 attached to the upper part of the windshield in the vehicle compartment mainly acquire images of the area ahead of the vehicle 12100. The imaging units 12102 and 12103 attached to the side mirrors mainly acquire images of the areas on the sides of the vehicle 12100. The imaging unit 12104 attached to the rear bumper or the back door mainly acquires images of the area behind the vehicle 12100. The forward images acquired by the imaging units 12101 and 12105 are mainly used for detecting a preceding vehicle, a pedestrian, an obstacle, a traffic light, a traffic sign, a lane, and the like.

Note that FIG. 27 shows an example of the imaging ranges of the imaging units 12101 to 12104. An imaging range 12111 represents the imaging range of the imaging unit 12101 attached to the front nose. Imaging ranges 12112 and 12113 respectively represent the imaging ranges of the imaging units 12102 and 12103 attached to the side mirrors. An imaging range 12114 represents the imaging range of the imaging unit 12104 attached to the rear bumper or the back door. For example, overlaying image data captured by the imaging units 12101 to 12104 offers an overhead image that looks down on the vehicle 12100.

At least one of the imaging units 12101 to 12104 may have a function of obtaining distance information. For example, at least one of the imaging units 12101 to 12104 may be a stereo camera including a plurality of image sensors, or may be an image sensor having pixels for phase difference detection.

For example, the microcomputer 12051 may extract especially a closest three-dimensional object on a traveling path of the vehicle 12100, the three-dimensional object traveling at a predetermined speed (for example, 0 km/h or higher) in a direction substantially the same as that of the vehicle 12100 as the preceding vehicle by determining a distance to each three-dimensional object in the imaging ranges 12111 to 12114 and change in time of the distance (relative speed relative to the vehicle 12100) on the basis of the distance information obtained from the imaging units 12101 to 12104. Moreover, the microcomputer 12051 can set an inter-vehicle distance to be secured in advance from the preceding vehicle, and can perform automatic brake control (including follow-up stop control), automatic acceleration control (including follow-up start control), and the like. In this manner, it is possible to perform the cooperative control for realizing automatic driving or the like to autonomously travel independent from the manipulation of the driver.

For example, the microcomputer 12051 can extract three-dimensional object data regarding the three-dimensional object while sorting the data into a two-wheeled vehicle, a regular vehicle, a large vehicle, a pedestrian, and other three-dimensional objects such as a utility pole on the basis of the distance information obtained from the imaging units 12101 to 12104 and use the data for automatically avoiding obstacles. For example, the microcomputer 12051 discriminates obstacles around the vehicle 12100 into an obstacle visibly recognizable to a driver of the vehicle 12100 and an obstacle difficult to visually recognize. Then, the microcomputer 12051 determines a collision risk indicating a degree of risk of collision with each obstacle, and when the collision risk is equal to or higher than a setting value and there is a possibility of collision, the microcomputer 12051 can perform driving assistance for avoiding the collision by outputting an alarm to the driver via the audio speaker 12061 and the display unit 12062 or performing forced deceleration or avoidance steering via the drive line control unit 12010.

At least one of the imaging units 12101 to 12104 may be an infrared camera for detecting infrared rays. For example, the microcomputer 12051 can recognize a pedestrian by determining whether or not there is a pedestrian in the captured images of the imaging units 12101 to 12104. Such pedestrian recognition is carried out, for example, by a procedure of extracting feature points in the captured images of the imaging units 12101 to 12104 as infrared cameras and a procedure of performing pattern matching processing on a series of feature points indicating an outline of an object to discriminate whether or not the object is a pedestrian. When the microcomputer 12051 determines that there is a pedestrian in the captured images of the imaging units 12101 to 12104 and recognizes the pedestrian, the audio and image output unit 12052 causes the display unit 12062 to superimpose a rectangular contour for emphasis on the recognized pedestrian. Furthermore, the audio and image output unit 12052 may causes the display unit 12062 to display icons or the like indicating pedestrians at desired positions.

An example of the vehicle control system to which the technology according to the present disclosure is applicable is heretofore described. The technology according to the present disclosure can be applied to the imaging unit 12031 and the like among the configurations described above. Specifically, the imaging apparatus 9 described with reference to FIG. 1 can be applied to the imaging unit 12031. By applying the technology according to the present disclosure to the imaging unit 12031, a captured image that is more viewable can be obtained, and thus driver fatigue can be reduced.

Finally, the description of each embodiment described above is an example of the present disclosure, and the present disclosure is not limited to the above-described embodiments. Therefore, it goes without saying that various changes, even those different from the above-described embodiments, can be made according to the design and the like without departing from the technical concept according to the present disclosure.

Furthermore, the drawings in the above-described embodiment are schematic, and the ratios and the like of the dimensions of each part do not always match the actual one. Furthermore, it is needless to say that the drawings may include some parts having different dimensional relationships and ratios among the drawings.

Note that the present technology may be configured as below.

(1) An image sensor including:

an imaging area in which a photoelectric conversion unit is formed on a semiconductor substrate and performs photoelectric conversion of incident light is arranged;

a wiring area having a wiring of transmitting a signal of the photoelectric conversion unit and arranged adjacent to a front surface of the semiconductor substrate;

a protective film that is arranged on a back surface that is a surface different from the front surface of the semiconductor substrate, and transmits the incident light and protects the back surface of the semiconductor;

an opening arranged in an outer peripheral area of the imaging area and opened from the protective film to any area of the semiconductor substrate and the wiring area; and

a protrusion arranged at a bottom of the opening.

(2) The image sensor according to (1), in which the opening is arranged in a vicinity of a connection portion arranged in the wiring area and used for connection with outside.

(3) The image sensor according to (1), in which the opening is a scribe area when an own image sensor formed on a semiconductor wafer is separated into individual pieces.

(4) The image sensor according to any of (1) to (3), in which the protrusion includes at least one of the semiconductor substrate, the wiring area, or the protective film.

(5) The image sensor according to any of (1) to (4), in which the protrusion is formed by transferring a shape of the protective film having been patterned to one of the semiconductor substrate and the wiring area.

(6) The image sensor according to (5), in which the protrusion is formed by the transfer when etching is performed using the patterned protective film as a mask.

(7) The image sensor according to any of (1) to (4), in which the protrusion is arranged at the bottom of the opening by being formed on the back surface of the semiconductor substrate before the protective film is arranged and by opening the arranged protective film to the semiconductor substrate.

(8) The image sensor according to any of (1) to (4), in which the protrusion is formed by etching the protective film and the semiconductor substrate by using a resist formed on the protective film as a mask.

(9) The image sensor according to any of (1) to (4), in which the protrusion includes the wiring area arranged in a recess formed on the front surface of the semiconductor substrate before the wiring area is arranged.

(10) The image sensor according to any of (1) to (4), further including:

an on-chip lens that is arranged adjacent to the protective film and collects the incident light to the photoelectric conversion unit,

in which

the protrusion is formed by transferring a shape of the on-chip lens to one of the semiconductor substrate and the wiring area.

(11) The image sensor according to any of (1) to (4), in which the protrusion includes the protective film arranged in a recess formed on the back surface of the semiconductor substrate before the protective film is arranged.

(12) A method for manufacturing an image sensor, the method including:

an imaging area forming step of forming, on a semiconductor substrate, an imaging area in which a photoelectric conversion unit that performs photoelectric conversion of incident light is arranged;

a wiring area arranging step of arranging a wiring area having a wiring of transmitting a signal of the photoelectric conversion unit, adjacent to a front surface of the semiconductor substrate;

a protective film arranging step of arranging a protective film that is arranged on a back surface that is a surface different from the front surface of the semiconductor substrate, and transmits the incident light and protects the back surface of the semiconductor;

an opening forming step of forming an opening arranged in an outer peripheral area of the imaging area and opened from the protective film to any area of the semiconductor substrate and the wiring area; and

a protrusion arranging step of arranging a protrusion at a bottom of the opening.

### REFERENCE SIGNS LIST

1 Image sensor
3 Circuit board
7 Bonding wire
9 Imaging apparatus
10 Imaging area
60 Peripheral pad area
71, 72 Connection portion
100 Pixel
120 Semiconductor substrate
122, 124, 124a, 126, 136 Protective film
130 Wiring area
131 Wiring
134 Bonding pad
137 Protrusion
154, 157 On-chip lens
155 In-layer lens
161, 162, 171 Opening
172, 172a, 172c, 172d, 172e, 172f, 172g, 172h, 172i, 172j, 172k,
172l, 172m, 182 Protrusion
181 Scribe area
1002 Image sensor
11402, 12031, 12101 to 12105 Imaging unit

1. An image sensor comprising:
an imaging area in which a photoelectric conversion unit is formed on a semiconductor substrate and performs photoelectric conversion of incident light is arranged;
a wiring area having a wiring of transmitting a signal of the photoelectric conversion unit and arranged adjacent to a front surface of the semiconductor substrate;
a protective film that is arranged on a back surface that is a surface different from the front surface of the semiconductor substrate, and transmits the incident light and protects the back surface of the semiconductor;
an opening arranged in an outer peripheral area of the imaging area and opened from the protective film to any area of the semiconductor substrate and the wiring area; and
a protrusion arranged at a bottom of the opening.

2. The image sensor according to claim 1, wherein the opening is arranged in a vicinity of a connection portion arranged in the wiring area and used for connection with outside.

3. The image sensor according to claim 1, wherein the opening is a scribe area when an own image sensor formed on a semiconductor wafer is separated into individual pieces.

4. The image sensor according to claim 1, wherein the protrusion includes at least one of the semiconductor substrate, the wiring area, or the protective film.

5. The image sensor according to claim 1, wherein the protrusion is formed by transferring a shape of the protective film having been patterned to one of the semiconductor substrate and the wiring area.

6. The image sensor according to claim 5, wherein the protrusion is formed by the transfer when etching is performed using the patterned protective film as a mask.

7. The image sensor according to claim 1, wherein the protrusion is arranged at the bottom of the opening by being formed on the back surface of the semiconductor substrate before the protective film is arranged and by opening the arranged protective film to the semiconductor substrate.

8. The image sensor according to claim 1, wherein the protrusion is formed by etching the protective film and the semiconductor substrate by using a resist formed on the protective film as a mask.

9. The image sensor according to claim 1, wherein the protrusion includes the wiring area arranged in a recess formed on the front surface of the semiconductor substrate before the wiring area is arranged.

10. The image sensor according to claim 1, further comprising:
an on-chip lens that is arranged adjacent to the protective film and collects the incident light to the photoelectric conversion unit,
wherein
the protrusion is formed by transferring a shape of the on-chip lens to one of the semiconductor substrate and the wiring area.

11. The image sensor according to claim 1, wherein the protrusion includes the protective film arranged in a recess formed on the back surface of the semiconductor substrate before the protective film is arranged.

12. A method for manufacturing an image sensor, the method comprising:
an imaging area forming step of forming, on a semiconductor substrate, an imaging area in which a photoelectric conversion unit that performs photoelectric conversion of incident light is arranged;
a wiring area arranging step of arranging a wiring area having a wiring of transmitting a signal of the photoelectric conversion unit, adjacent to a front surface of the semiconductor substrate;
a protective film arranging step of arranging a protective film that is arranged on a back surface that is a surface different from the front surface of the semiconductor substrate, and transmits the incident light and protects the back surface of the semiconductor;
an opening forming step of forming an opening arranged in an outer peripheral area of the imaging area and opened from the protective film to any area of the semiconductor substrate and the wiring area; and
a protrusion arranging step of arranging a protrusion at a bottom of the opening.
